(19) United States
(12) Patent Application Publication
(10) Pub. No.: US 2013/0082843 A1
(43) Pub. Date: Apr. 4, 2013

(54) DETECTION OF FRACTURE OF DISPLAY PANEL OR OTHER PATTERNED DEVICE

(71) Applicants: Joshua Grey Wurzel, Sunnyvale, CA (US); Yafei Bi, Palo Alto, CA (US); Wei H. Yao, Palo Alto, CA (US)

(72) Inventors: Joshua Grey Wurzel, Sunnyvale, CA (US); Yafei Bi, Palo Alto, CA (US); Wei H. Yao, Palo Alto, CA (US)

(73) Assignee: APPLE INC., Cupertino, CA (US)

(21) Appl. No.: 13/308,094

(22) Filed: Nov. 30, 2011

Related U.S. Application Data
(60) Provisional application No. 61/542,091, filed on Sep. 30, 2011.

(51) Int. Cl. G08B 21/00; B23P 11/00; G01R 31/08; G01R 27/02

(52) U.S. Cl. 340/635; 29/593; 324/525

(57) ABSTRACT

Systems, methods, and devices for detecting display panel or other patterned device fractures or microfractures using outer resistive trace(s) on the display panel or the other patterned device. To provide just one example, a system may include a display and data processing circuitry. The display may include a display panel with an outer resistive trace disposed near edges of the display panel. The display may include discontinuity detection circuitry that can detect the occurrence of a discontinuity of the outer resistive trace. The data processing circuitry may determine whether the display panel is likely to suffer a catastrophic failure based at least in part on the occurrence of the discontinuity. The data processing circuitry may also cause the display to display a user warning when the display panel is likely to suffer the catastrophic failure.

### BACKGROUND

The present disclosure relates generally to electronic display panels and/or other patterned devices and, more particularly, to display panels and/or other patterned devices having outer resistive trace(s) whose resistances correspond to dimensions or to the integrity of the display panel and/or other patterned device.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

A variety of electronic devices use electronic displays, such as liquid crystal displays (LCDs) and/or organic light emitting diode (OLED) displays, to display images, videos, and user interfaces. These electronic displays may be installed in the electronic devices to fit within an disclosure and around other electronic device components. If the dimensions of the display are not within a particular tolerance, the display could be too small (and thus loose) or too large (and thus not fit).

To ensure an electronic display is sized correctly, workers may use precise instruments such as calipers to measure the display after it has been fabricated, cut, and polished. Although generally effective, this technique is labor-intensive and prone to mistakes due to human error. Moreover, the tolerance of the size of the electronic display panels is constrained by the precision of the calipers and human workers, as well as the capabilities of the cutting and grinding tools to precisely cut and grind the display panels to the desired size. However, because consumers desire smaller electronic devices with increased functionality, device makers may desire tighter tolerances to reduce the amount of unused space within an electronic device.

In addition, electronic display panels may occasionally crack and break. Often, cracks may form in stages, beginning as microfractures that only eventually result in catastrophic display failure. For example, microfractures in a display panel may arise due to a flaw in the manufacturing process or due to being dropped or crushed during use. It may be difficult to detect when fractures or microfractures occur.

The various problems discussed above may also generally apply to other patterned devices. For example, touch screen panel size and precision may likewise be constrained by human workers and the capabilities of cutting and grinding tools. Flexible printed circuits (FPCs) may be occasionally mis-punched by die-punching machinery, and printed circuit boards (PCBs) may be drilled out to erroneous sizes. Though human workers can attempt to identify and alleviate such problems, doing so may be labor-intensive and error-prone. Additionally, touch screens, FPCs, and PCBs may crack or tear after manufacturing. It may also be difficult to identify when or where such cracks or tears occur in touch screen panels, FPCs, and PCBs, and/or other patterned devices.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the present disclosure relate to systems, methods, and devices for detecting display panel or other patterned device fractures or microfractures using outer resistive trace(s) on a display panel. To provide just one example, a system may include a display and data processing circuitry. The display may include a display panel with an outer resistive trace disposed near edges of the display panel. The display may include discontinuity detection circuitry that can detect the occurrence of a discontinuity of the outer resistive trace. The data processing circuitry may determine whether the display panel is likely to suffer a catastrophic failure based at least in part on the occurrence of the discontinuity. The data processing circuitry may also cause the display to display a user warning when the display panel is likely to suffer the catastrophic failure.

Outer resistive trace(s) may also allow the detection of fractures or microfractures of a display panel or other patterned device in other contexts. For example, the outer resistive trace(s) may be monitored during the manufacture of electronic devices with displays. In so doing, fractures or microfractures in the display panels of such displays may be detected. If particular processes or manufacturing lines are producing inordinate fractures or microfractures, processes may be improved and/or manufacturing lines changed.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a schematic block diagram of an electronic device with an electronic display having outer resistive trace(s) whose resistance correspond to the dimensions of the display panel, in accordance with an embodiment;

FIG. 2 is a perspective view of an example of the electronic device of FIG. 1 in the form of a computer, in accordance with an embodiment;

FIG. 3 is a front view of an example of the electronic device of FIG. 1 in the form of a handheld device, in accordance with an embodiment;

FIG. 4 is a schematic diagram of a display panel having a single resistive trace disposed near its edges, in which the geometry of the single resistive trace after grinding relates to the dimensions of the display panel, in accordance with an embodiment;

FIGS. 5 and 6 are schematic diagrams of a display panel having multiple resistive traces disposed its edges, in which the number of the multiple resistive traces remaining after grinding relate to the dimensions of the display panel, in accordance with an embodiment;

FIGS. 7 and 8 are schematic block diagrams of systems to test the dimensions of a display panel by measuring the resistance of outer resistive trace(s) of the display panel, in accordance with embodiments;

FIG. 9 is a flowchart describing a method for determining whether a display panel has been cut and/or polished to within a tolerance of specified dimensions, in accordance with an embodiment;

FIG. 10 is a schematic diagram of a display panel having at least one outer resistive trace, in which the display panel has been cut and/or polished to improper dimensions, in accordance with an embodiment;

FIG. 11 is a schematic diagram of a display panel having an outer resistive trace, in which the display panel has been cut and/or polished to proper dimensions, in accordance with an embodiment;

FIG. 12 is a flowchart describing a method for determining whether a display panel has been cut and/or polished to proper proportions, in accordance with an embodiment;

FIGS. 13 and 14 are circuit diagrams representing a Wheatstone bridge circuit that can be formed using the outer resistive trace(s) of a display panel, in accordance with an embodiment;

FIGS. 15-18 are circuit diagrams of circuitry that may be used to discern relationships regarding the size and/or proportions of a display panel using the Wheatstone bridge circuit of FIG. 13 or 14, in accordance with embodiments;

FIG. 19 is a flowchart describing a method for determining whether a display panel has been cut and/or polished to proper proportions using the Wheatstone bridge circuits of FIG. 13 or 14, in accordance with an embodiment;

FIG. 20 is a diagram of a circuit that may enable the determination of the resistance of each segment of outer resistive trace(s) of a display panel, in accordance with an embodiment;

FIG. 21 is a flowchart describing a method for determining the resistances of the segments of the outer resistive trace(s) of a display panel using the circuit of FIG. 20, in accordance with an embodiment;

FIG. 22 is a flowchart describing a method for determining whether a display panel has been cut and/or polished to within a tolerance of specified dimensions using the circuit and method of FIGS. 20 and 21, in accordance with an embodiment;

FIG. 23 is a schematic block diagram of a system for grinding a display panel to specified dimensions based at least partly on a resistance of outer resistive trace(s), in accordance with an embodiment;

FIGS. 24-26 are flowcharts describing embodiments of methods for manufacturing a display panel to specified dimensions based at least partly on the resistance of outer resistive trace(s), in accordance with an embodiment;

FIG. 27 is a schematic diagram illustrating a display panel with multiple outer resistive traces patterned on the display panel such that properly grinding each display panel edge involves grinding away a different one of the outer resistive traces, in accordance with an embodiment;

FIG. 28 is a flowchart describing a method for manufacturing a display panel to specified dimensions using the outer resistive traces illustrated in FIG. 27, in accordance with an embodiment;

FIGS. 29 and 30 represent front and back views, respectively, of a display panel with outer resistive trace(s) that can be used to detect the location of microfractures that occur in the display panel, in accordance with an embodiment;

FIGS. 31 and 32 are schematic block diagrams representing systems for monitoring the integrity of a display panel using time domain reflectance (TDR), in accordance with an embodiment;

FIG. 33 is a flowchart describing a method for detecting the location of a microfracture along an edge of a display panel, in accordance with an embodiment;

FIG. 34 is a flowchart for monitoring the integrity of a display panel based at least partly on a change in resistance or a change in relationship between resistances of outer resistive trace(s) of a display panel over time, in accordance with an embodiment;

FIG. 35 is a flowchart for quality control by monitoring the integrity of a display panel during the manufacture of an electronic device, in accordance with an embodiment;

FIG. 36 is a flowchart describing a method for monitoring the statistical location of microfractures in display panels occurring in daily use of an electronic device, in accordance with an embodiment;

FIG. 37 is a flowchart describing a method for warning an electronic device user when a microfracture of a display panel indicates eminent display failure, in accordance with an embodiment;

FIG. 38 is a circuit diagram illustrating a Wheatstone bridge circuit that may be used to ascertain the total resistance of outer resistive trace(s) of a display panel, in accordance with an embodiment; and

FIG. 39 is a circuit diagram illustrating a Wheatstone bridge circuit that may be used to ascertain the resistance of a segment of outer resistive trace(s) of a display panel, in accordance with an embodiment.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but may nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present disclosure relates to display panels and/or other suitable patterned devices having outer resistive trace(s) disposed near device edges. Such patterned devices may include display panels, as mentioned, but may also include touch sensor panels (e.g., single-sided indium tin oxide (SITO) or double-sided indium tin oxide (DITO) touch sensor panels), flexible printed circuits (FPCs), printed circuit boards (PCBs), or any other suitable patterned devices. Although the following disclosure describes the use of outer resistive traces with particular emphasis on display panels, it should be appreciated that outer resistive traces may be used with any suitable patterned devices. In other words, elements of the discussion below which relate to display panels should be understood to encompass any suitable patterned devices used in addition to, or in lieu of, display panels.

In the disclosure that follows, display panels are described which use a single outer resistive trace or multiple outer resistive traces, as desired. Thus, the present disclosure refers to “outer resistive trace(s)” or “at least one outer resistive trace” as acknowledging that one or more than one resistive trace may be employed. Since the resistance of a material deposited onto or into a display panel will vary depending on the geometry of the material, the outer resistive trace(s) may have a resistance that depends upon the dimensions of the outer resistive trace(s). For example, wider outer resistive trace(s) may have relatively lower resistances than thinner outer resistive trace(s). Thus, as the outer resistive trace(s) are partially polished away during a grinding process of manufacturing, the resistances of the outer resistive trace(s) will become higher.

From the relationship between the geometry of the outer resistive trace(s) and resistance, the resistance of the outer resistive trace(s) may be used to verify that a display panel has been cut and/or polished, or ground down, to specified dimensions. As used herein, the terms “ground,” “ground down,” “grinded,” and “polished” all generally refer to the effect of grinding to achieve more precise dimensions. In one example, the outer resistive trace(s) or segments of the outer resistive trace(s) may have specific resistances when the display panel has been properly polished, or ground down, to size. Likewise, the resistances of segments of the outer resistive trace(s) may have particular proportions when the display panel has been properly ground. In addition, the outer resistive trace(s) may enable a manner of cutting and grinding display panels to precise dimensions. By grinding the display panels while periodically monitoring the resistance of the outer resistive trace(s), the display panels may be ground down to precise specified dimensions.

In some cases, display panels need not be further polished or ground down, but may instead be recut to obtain more accurate and/or precise dimensions. Likewise, certain patterned devices may not typically undergo a polishing or grinding process (e.g., flexible printed circuits (FPCs)). Such patterned devices instead may be cut or recut to proper dimensions, if possible.

Additionally or alternatively, outer resistive trace(s) that remain around the edges of the display panel after the display panels have been cut and/or polished can be used to detect locations in the display panel where microfractures arise. For example, using time domain reflectance (TDR) or resistance detection circuitry, a location of a microfracture occurring along the edge of a display panel can be detected. Indeed, the location of a microfracture may be detected before a more serious display panel fracture occurs, allowing device manufacturers to identify potential problems before the devices reach the hands of users. Additionally or alternatively, an electronic device may monitor the integrity of a display panel installed within the electronic device, warning users when a microfracture arises before it results in a catastrophic failure.

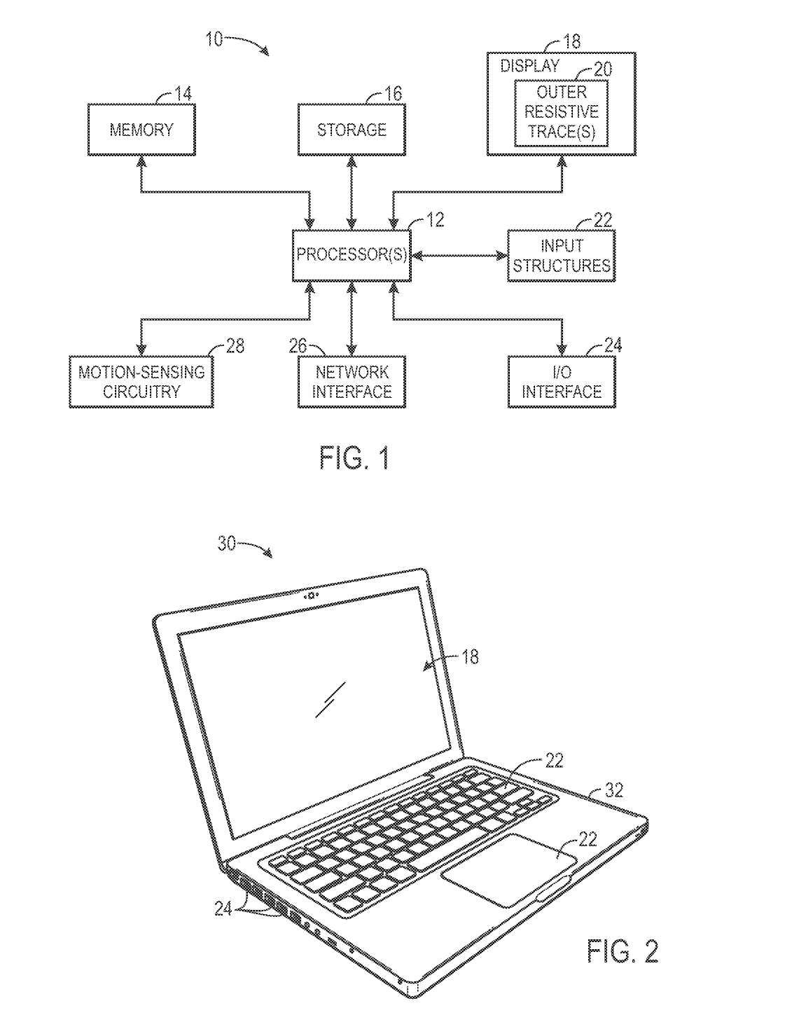

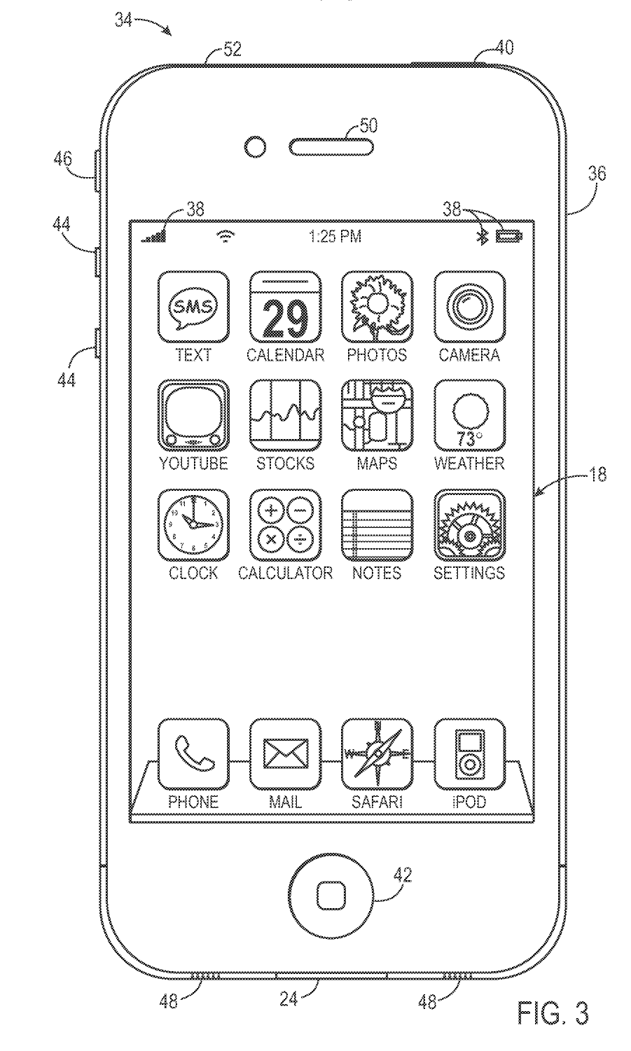

A variety of electronic devices may incorporate the electronic displays and/or other patterned devices mentioned above. One example appears in a block diagram of FIG. 1, which describes an electronic device 10 that may include, among other things, one or more processor(s) 12, memory 14, nonvolatile storage 16, a display 18 having outer resistive trace(s) 20, input structures 22, an input/output (I/O) interface 24, network interfaces 26, and/or motion-sensing circuitry 28. The various functional blocks shown in FIG. 1 may include hardware, executable instructions, or a combination of both. In the present disclosure, the processor(s) 12 and/or other data processing circuitry may be generally referred to as “data processing circuitry.” This data processing circuitry may be embodied wholly or in part as software, firmware, hardware, or any combination thereof. Furthermore, the data processing circuitry may be a single, contained processing module or may be incorporated wholly or partially within any of the other elements within the electronic device 10. FIG. 1 is merely one example of a particular implementation and is intended to illustrate the types of components that may be present in electronic device 10. These components may be found in various examples of the electronic device 10. By way of example, the electronic device 10 of FIG. 1 may represent a block diagram of a computer as depicted in FIG. 2, a handheld as device depicted in FIG. 3, or similar devices.

As shown in FIG. 1, the processor(s) 12 and/or other data processing circuitry may be operably coupled with the memory 14 and the nonvolatile storage 16. In this way, the processor(s) 12 may execute instructions to carry out various functions of the electronic device 10. Among other things, these functions may include generating image data to be displayed on the display 18 or testing the condition (e.g., quality and/or geometry) of the display 18 based on the outer resistive trace(s) 20. The programs or instructions executed by the processor(s) 12 may be stored in any suitable article of manufacture that includes one or more tangible, computer-readable media at least collectively storing the instructions or routines, such as the memory 14 and/or the nonvolatile storage 16. The memory 14 and the nonvolatile storage 16 may represent, for example, random-access memory, read-only memory, rewritable flash memory, hard drives, and optical discs.

The display 18 may be any suitable electronic display with a display panel incorporating the outer resistive trace(s) 20. For example, the display 18 may be a liquid crystal display (LCD) or an organic light emitting diode (OLED) display. In some embodiments, the display 18 may also serve as a touch-screen input device. For example, the display 18 may be a MultiTouch™ touch screen device that can detect multiple touches at once.

The outer resistive trace(s) 20 may be patterned along or near the outer edges of a display panel of the display 18. In some cases, the outer resistive trace(s) 20 will serve essentially no purpose in the operation of the electronic device 10 after manufacture. That is, the outer resistive trace(s) may remain, in a vestigial manner, after having been used previously during manufacturing to ensure the display 18 or the electronic device 10 has been manufactured properly. In these cases, the outer resistive trace(s) 20 may simply have resistances indicative that the display panel of the display 18 has the proper dimensions, but may not be otherwise used (any more) in the electronic device 10. In other cases, the outer resistive trace(s) 20 may be used to identify certain newly arising flaws in the electronic device 10 after manufacturing. Namely, by occasionally detecting changing resistances in the outer resistive trace(s) 20, the location and/or occurrence of a fracture or microfracture in the display 18 may be determined. Additionally or alternatively, time domain reflectance (TDR) may be used to identify the location and/or occurrence of a fracture or microfracture.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interfaces 26. The network interfaces 26 may include, for example, interfaces for a personal area network (PAN), such as a Bluetooth network, for a local area network (LAN), such as an 802.11x Wi-Fi network, and/or for a wide area network (WAN), such as a 3G or 4G cellular network. The motion-sensing circuitry 28 may include accelerometers, a gyroscope, and/or a compass to detect position changes of the electronic device 10.

The electronic device 10 may take the form of a computer or other type of electronic device. For example, the electronic device 10 in the form of a computer may be a model of a MacBook®, MacBook® Pro, MacBook Air®, iMac®, Mac® mini, or Mac Pro® available from Apple Inc. FIG. 2 provides one example of the electronic device 10 in the form of a notebook computer 30. The computer 30 may include a housing 32, a display 18, input structures 22, and ports of an I/O interface 24. The input structures 22, such as a keyboard and/or touchpad, may be used to interact with the computer 30. Via the input structures 22, a user may start, control, or operate a GUI or applications running on computer 30.

The computer 30 may include the display 18. Thus, the dimensions of the display 18 may be relatively precisely cut and/or polished (e.g., to a tolerance of within 150 to 300 μm or smaller) based on manufacturing techniques involving the outer resistive trace(s) 20. Additionally or alternatively, the location and/or occurrence of fractures or microfractures of the display 18 may be detected using the outer resistive trace(s) 20.

The electronic device 10 may also take the form of a handheld device 34, as generally illustrated in FIG. 3. The handheld device 34 may represent, for example, a portable phone, a media player, a personal data organizer, a handheld game platform, or any combination of such devices. By way of example, the handheld device 34 may be a model of an iPod® or iPhone® available from Apple Inc. of Cupertino, Calif. In other embodiments, the handheld device 34 may be a tablet-sized embodiment of the electronic device 10, which may be, for example, a model of an iPad® available from Apple Inc.

The handheld device 34 may include an enclosure 36 to protect interior components from physical damage and to shield them from electromagnetic interference. The enclosure 36 may surround the display 18, which may display indicator icons 38. The indicator icons 38 may indicate, among other things, a cellular signal strength, Bluetooth connection, and/or battery life. The I/O interfaces 24 may open through the enclosure 36 and may include, for example, a proprietary I/O port from Apple Inc. to connect to external devices. User input structures 40, 42, 44, and 46, in combination with the display 18, may allow a user to control the handheld device 34. A microphone 48 may obtain a user's voice for various voice-related features, and a speaker 50 may enable audio playback and/or certain phone capabilities. A headphone input 52 may provide a connection to external speakers and/or headphones.

Like the display 18 of the computer 30, the dimensions of the display 18 may be relatively precisely cut and/or polished (e.g., to a tolerance of within 150 to 300 μm) based on manufacturing techniques involving the outer resistive trace(s) 20. Additionally or alternatively, the location and/or occurrence of fractures or microfractures of the display 18 may be detected using the outer resistive trace(s) 20.

Regardless of the form taken by the electronic device 10, the display 18 must be manufactured before the display 18 can be installed within the electronic device 10. As will be discussed below, the manufacturing process of the display 18 may involve verifying a display panel of the electronic device 18 has the proper specified dimensions based on the outer resistive trace(s) 20 patterned around or near the edges of the display panel. Indeed, cutting and grinding each edge of the display panel may involve monitoring the resistance of the outer resistive trace(s) 20. In manufacturing the display 18, display panels may be fabricating in a batch and cut into individual, unground display panels of relatively coarse sizes. These unground display panels may then be ground down more finely to ultimate specified dimensions.

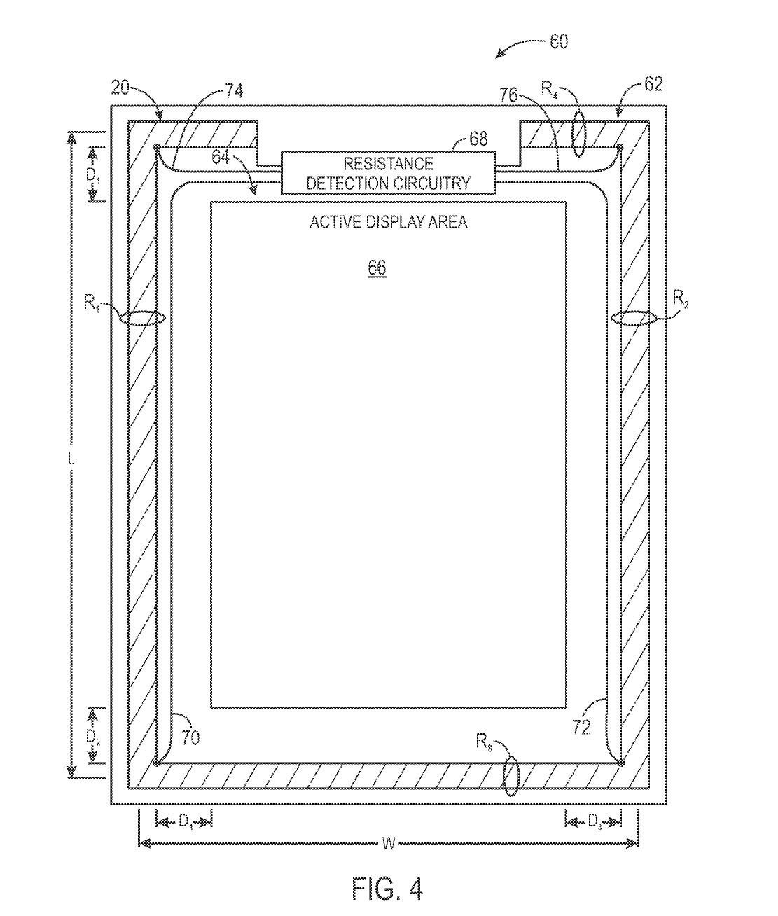

One example of an unground display panel 60 of the electronic display 18 appears in FIG. 4. Although FIG. 4 illustrates the display panel 60 in particular, the general arrangement of outer resistive trace(s) 20 and associated circuitry may also be employed in a touch sensor panel (e.g., a single-sided indium tin oxide (SITO) or double-sided indium tin oxide (DITO) touch sensor panel), a flexible printed circuit (FPC), a printed circuit board (PCB), or any other suitable patterned device. Where the present disclosure refers to the manufacture of the display panel 60, any of these other patterned devices generally may be employed in addition to, or in lieu of, the display panel 60. The unground display panel 60 of FIG. 4 represents an example of a display panel 60 after it has been fabricated and cut from a batch of contiguous display panels 60, but before being ground down to its final specified dimensions. As illustrated in FIG. 4, the display panel 60 includes an outer resistive trace 20 that has been patterned at least partially in a dead zone 62 of the display panel 60. As used herein, the term “dead zone” refers to an outer portion of a display panel that typically does not include much, if any, driving circuitry. Indeed, at least part of the dead zone 62 of the display panel 60 will be ground away during the manufacturing process. The dead zone 62 may be contrasted with a peripheral circuitry area 64 of the display panel 60 and an active display area 66. The peripheral circuitry area 64 may contain circuitry used to support the active display area 66, such as row and column driver circuitry, or any other suitable support circuitry. The active display area 66 represents any suitable display area used to display imagery. By way of example, the active display area 66 may be an active area of a liquid crystal display (LCD) or an organic light emitting diode (OLED) display.

In the example of FIG. 4, the outer resistive trace 20 is patterned near edges of the display panel 60 at least partially in the dead zone 62. The outer resistive trace 20 may be formed using any suitable conductive material having a resistance that varies according to geometry. Among other things, the outer resistive trace 20 may be formed from an opaque material (e.g., any suitable metal) and/or a transparent conductive material (e.g., indium tin oxide (ITO)). In some embodiments, the outer resistive trace 20 is a material that also forms the active display area 66. For example, the outer resistive trace 20 may be formed from the same material used to pattern a black matrix material delineating pixels of the active display area 66. In another example, the outer resistive trace 20 may be formed from the same material used to pattern pixel electrodes, common electrodes, OLEDs, gate lines, or source lines, or some combination of these components that may form the active display area 66. Alternatively, the outer resistive trace 20 may be patterned at a different time from that of the active display area 66. Although the display panel 60 is illustrated as rectangular, and thus includes the outer resistive trace 20 near the four edges of the display panel 60, the display panel 60 may have any number of sides. Indeed, the display panel 60 may even have rounded edges or form a circle with only one continuous edge.

It should be appreciated that the outer resistive trace 20 may take any pattern and need not be a single trace of a particular width. Indeed, traces near different edges of the display panel 60 may have different sizes or may be arranged in a different pattern. Depending on the amount of circuitry to be patterned in the peripheral circuitry area 64 and the dead zone 62, a different amount of space may be available for the outer resistive trace(s) 20. The pattern and size of the outer resistive trace(s) 20 may vary accordingly.

When the outer resistive trace 20 is patterned at the same time that a component of the active display area 66 is patterned, the outer resistive trace 20 may have a precise distance apart from the active display area 66. In FIG. 4, the distances from the closest edge of the outer resistive trace 20 and the nearest edge of the active display area 66 are generally illustrated as D₁, D₂, D₃, and D₄, respectively. Dimensions L and W shown in FIG. 4 refer to the ultimate specified dimensions of the display panel 60 the display panel 60 should have after being cut and/or polished. Thus, as seen in FIG. 4, the act of grinding the display panel 60 to the specified dimensions of the display panel 60 may involve partially removing some of the outer resistive trace 20. Removing part of the outer resistive trace 20 will cause the outer resistive trace 20 to increase in resistance as it becomes smaller. As will be described below, the resistance of the outer resistive trace 20 may indicate whether the correct amount of the display 60 edges have been ground away, giving the display panel 60 the specified dimensions. The resistances of certain segments of the outer resistive trace 20 along the edges of the display panel 60 may have resistances respectively denoted in FIG. 4 as R₁, R₂, R₃, and R₄. It should be appreciated that, in certain embodiments, the resistance of the outer resistive trace(s) 20 need not be uniform at all points as long as what the resistance is supposed to be can be determined.

To detect the resistance of the outer resistive trace 20, resistance detection circuitry 68 may be disposed in the peripheral circuitry area 64 of the display panel 60. The resistance detection circuitry 68 generally may detect an indication of the resistance of the outer resistive trace 20. The resistance detection circuitry 68 may be or may employ a component of other circuitry of the peripheral circuitry area 64, such as driver circuitry for the active display area 66. Thus, in some embodiments, data from the resistance detection circuitry 68 may be provided to other circuitry external to the display panel 60 (e.g., the processor(s) 12) may take place using the same channels as used by driver circuitry of the display panel 60.

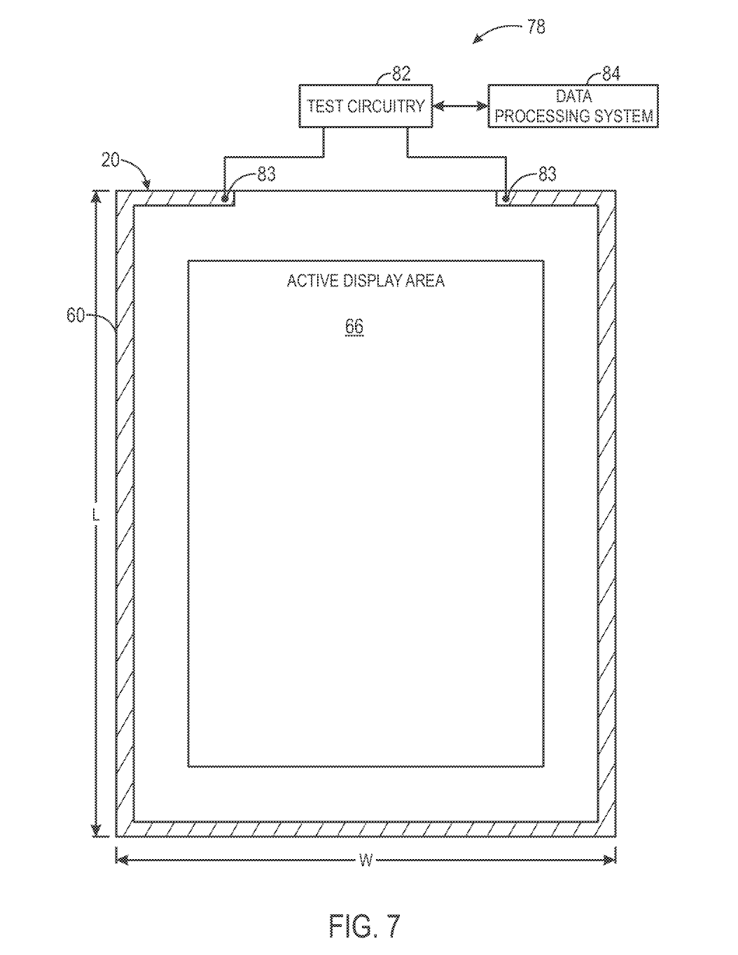

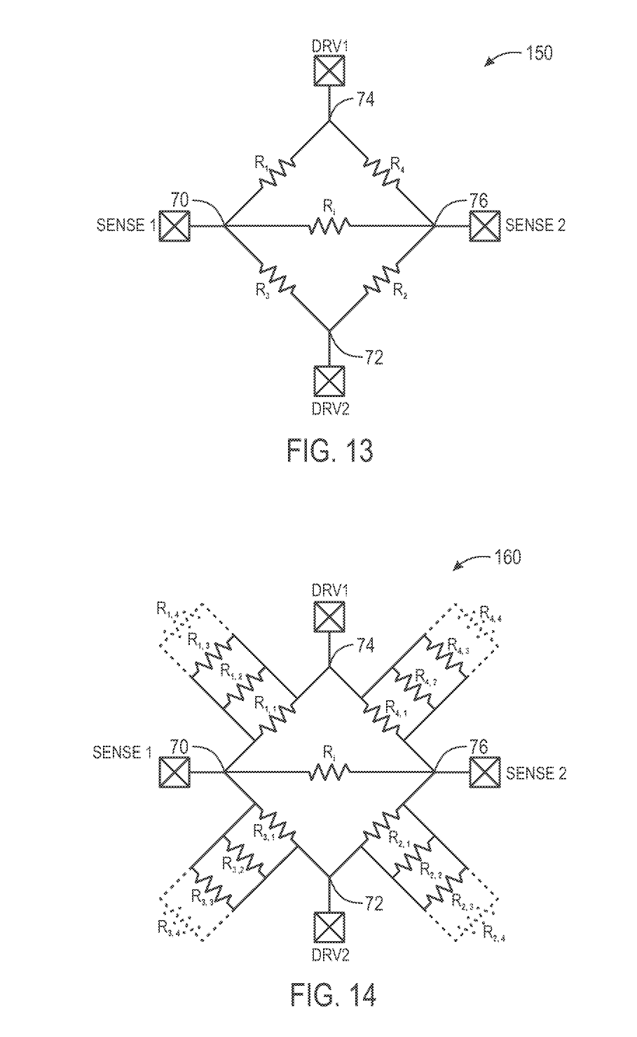

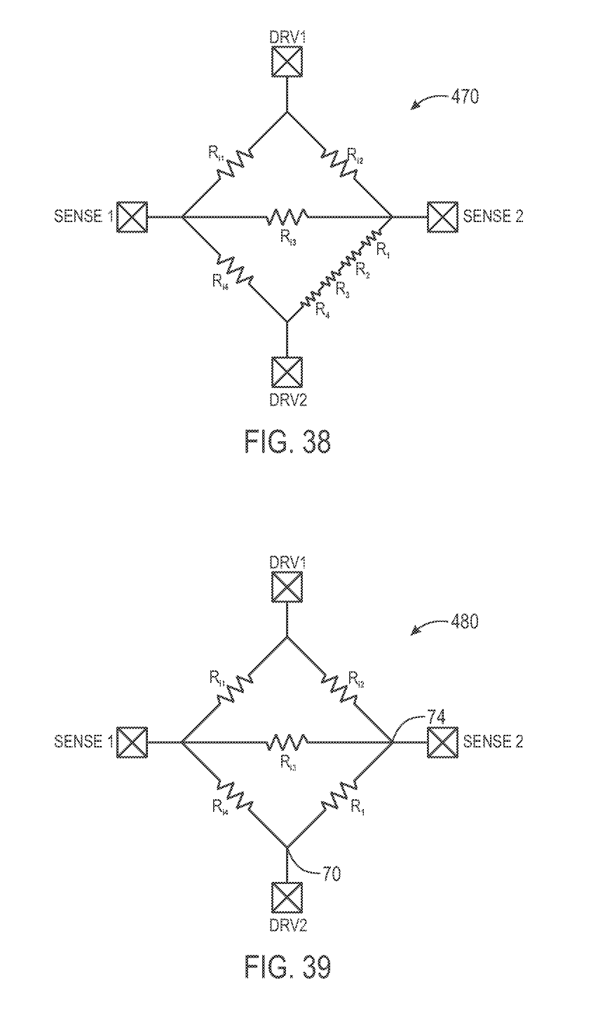

The resistance detection circuitry 68 may include any suitable circuitry that can indicate a total resistance of the outer resistive trace 20, the resistance of certain segments of the outer resistive trace, and/or a relationship between certain segments of the outer resistive trace 20. For example, in some embodiments, the resistance detection circuitry 68 may employ a Wheatstone bridge circuit in the manner of FIG. 38 or FIG. 39 to detect the total resistance of the outer resistive trace 20 or a segment of the outer resistive trace 20, respectively. Additionally or alternatively, the resistance detection circuitry 68 may employ a Wheatstone bridge circuit in the manner of FIG. 13 to detect a relationship between segments of the outer resistive trace 20. In some embodiments, the resistance detection circuitry 68 may include circuitry such as that illustrated in FIG. 20, which may enable a determination of the resistance of all segments of the outer resistive trace 20 (e.g., R₁, R₂, R₃, and R₄). Depending on the circuitry used by the resistance detection circuitry 68, various embodiments of the display panel 60 may or may not include connections 70, 72, 74, and 76 to corners of the outer resistive trace 20 of the display panel 60. The circuits of FIGS. 13, 20, 38, and 39 that may be used in the resistance detection circuitry 68 will be discussed in greater detail below. In addition, it should be appreciated that some embodiments of the display panel 60 may not employ any resistance detection circuitry 68 on the display panel 60. For such embodiments, the resistance of the outer resistive trace 20 and/or segments of the outer resistive trace 20 may be measured using external test circuitry (e.g., in the manner of FIG. 7, which is discussed further below).

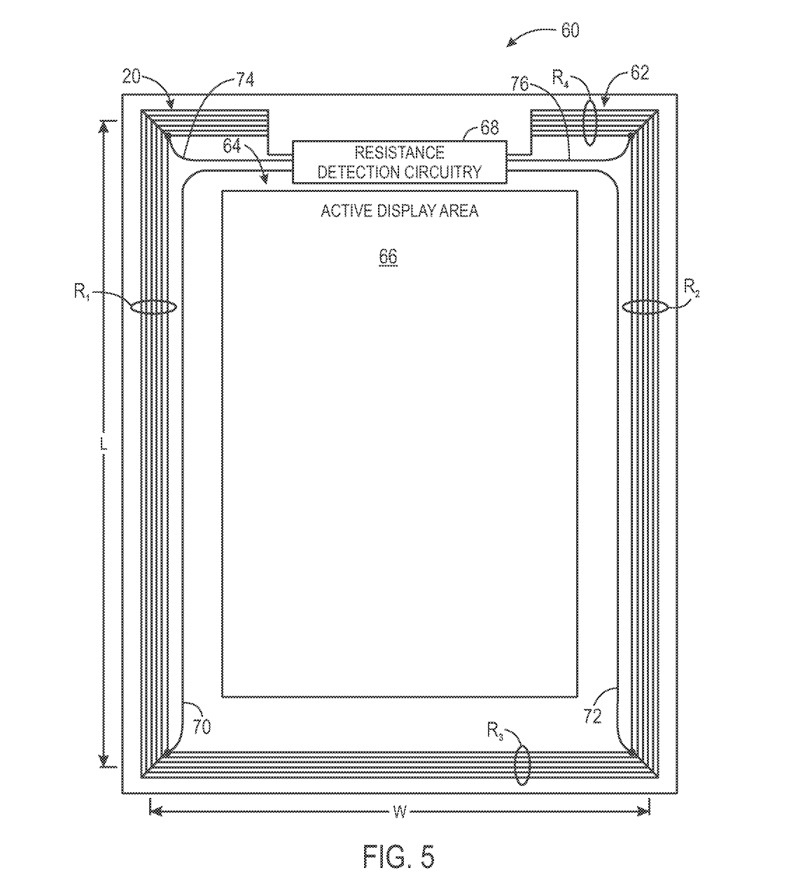

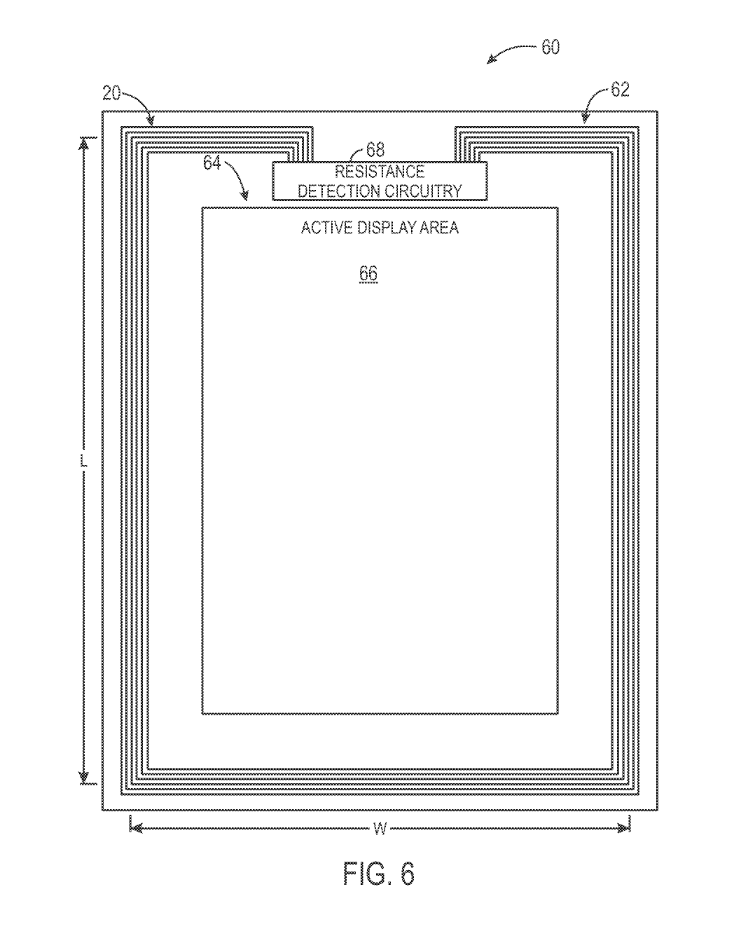

Although only one outer resistive trace 20 is shown in FIG. 4, more than one outer resistive trace 20 may be employed in the display panel 60. For example, FIGS. 5 and 6 are schematic diagrams of display panels 60 having multiple outer resistive traces 20 instead of a single, relatively wider analog outer resistive trace 20. In the examples of both FIGS. 5 and 6, the multiple outer resistive traces 20 are at least partially patterned in the dead zone 62 of the display panel 60. The peripheral circuitry area 64 is shown to include the resistance detection circuitry 68, which may operate in substantially the same manner as discussed above with reference to FIG. 4. Alternatively, the display panel 60 may not include the resistance detection circuitry 68, and may instead rely on some form of external test circuitry (e.g., in the manner of FIG. 7, which is discussed further below). It should be appreciated that different patterns of outer resistive trace(s) 20 than those illustrated in FIGS. 4, 5, and 6 may be employed. Indeed, different patterns of trace(s) of the same or different widths may be used near different edges of the display panel 60.

In the example of FIG. 5, the multiple resistive traces 20 are connected in parallel. Thus, the removal of any segment of one of the outer resistive traces 20 will increase the total resistance of the outer resistive traces 20 by some discrete amount. Thus, depending on the number of the outer resistive traces 20 that remain in a segment of the outer resistive traces 20, that segment will have a different resistance. When the display panel 60 has been properly cut and/or polished, a certain number of the outer resistive traces 20 may have been removed and a certain number may remain. Based on the resistance of the segments of the outer resistive traces 20 (e.g., the resistances R₁, R₂, R₃, and R₄), the total resistance of the outer resistive traces 20, and/or the relationship between resistances of the segments of the outer resistive traces 20, the number of traces of the outer resistive traces 20 remaining may be ascertained. In this way, whether the display panel 60 has been properly cut and/or polished may be ascertained.

By contrast, in the example of FIG. 6, the multiple resistive traces 20 are concentric and are not connected in parallel with one another. As such, the multiple resistive traces are individually detectable by the resistance detection circuitry 68. That is, the complete removal of any part of one of the outer resistive trace(s) 20 will cause that outer resistive trace 20 to be detectable as having an essentially infinite resistance. The resistance detection circuitry 68 may be able to discretely determine the number of edges of the display panel 60 that have not been ground away. For instance, grinding any edge of the display panel 60 too much, such that one of the multiple outer resistive traces 20 is ground away in at least one place, may be easily detectable in the resistance detection circuitry 68 as an infinite resistance.

As mentioned above, the resistance detection circuitry 68 may include any suitable circuitry to enable a general detection of the resistance of the outer resistive trace(s) 20. In one example, a Wheatstone bridge circuit 470 may enable the detection of the entire resistance of the display panel 60, as generally illustrated in FIG. 38. In general, a Wheatstone bridge circuit enables the detection of an unknown resistance based on a voltage difference occurring between to legs of a resistive bridge. In the example of FIG. 38, known internal resistances Rᵢ₁, Rᵢ₂, Rᵢ₃, and Rᵢ₄ make up known segments of the Wheatstone bridge circuit 470. These internal resistances may be any suitable known values. Because three out of the four outer resistive legs of the Wheatstone bridge circuit 470 are known (Rᵢ₁, Rᵢ₂, and Rᵢ₄) and only one of the four is unknown (the sum of the resistances R₁, R₂, R₃, and R₄), the voltage values at SENSE1 and SENSE2 contacts can indicate the resistance of the unknown leg.

To provide one example, each of the internal resistances Rᵢ₁, Rᵢ₂, and Rᵢ₄ may be individually equal to the sum of the resistances R₁, R₂, R₃, and R₄ expected to occur when the display panel 60 has been properly cut and/or polished. Power may be applied across driving contacts DRV1 and DRV2. If the bridge circuit is balanced (e.g., the ratio of Rᵢ₁:Rᵢ₄ is the same as Rᵢ₂:R₁+R₂+R₃+R₄), the voltages appearing at the SENSE1 and SENSE2 contacts should be the same. When each of the internal resistances Rᵢ₁, Rᵢ₂, and Rᵢ₄ are individually equal to the sum of the resistances R₁, R₂, R₃, and R₄ that occur when the display panel 60 has been properly cut and/or polished, equal voltages at the SENSE1 and SENSE2 contacts indicate that the display panel 60 has the proper dimensions. Any SENSE1 and SENSE2 voltage deviations may be used to determine any other values of the sum of the resistances R₁, R₂, R₃, and R₄ based on their relationship to the known resistances Rᵢ₁, Rᵢ₂, and Rᵢ₄. Based on the same principles, the known internal resistances Rᵢ₁, Rᵢ₂, and Rᵢ₄ may be any other suitable values. Because these internal resistance values are known, the voltages at the SENSE1 and SENSE2 contacts may vary in a particular way as the sum of the resistances R₁, R₂, R₃, and R₄ of the outer resistive trace(s) 20 varies.

Similarly, FIG. 39 illustrates an example of a Wheatstone bridge circuit 480. The Wheatstone bridge circuit 480 may generally operate in the same manner as the Wheatstone bridge circuit 470. However, the Wheatstone bridge circuit 480 may measure only one segment of the outer resistive trace(s) 20. In the example of FIG. 39, the Wheatstone bridge circuit 480 measures the resistance of the segment of the outer resistive trace(s) 20 between points 74 and 70 (R₁). The resistance detection circuitry 68 may also include other similar Wheatstone bridge circuits to measure other segments of the outer resistive trace(s) 20. In this way, the resistance detection circuitry 68 may detect any or all resistances of the outer resistive trace(s) 20. In some embodiments, the voltages detected at the SENSE1 and SENSE2 contacts of the Wheatstone bridge circuits 470 and 480 may be compared using circuitry such as that described below with reference to FIGS.

Whether the display panel 60 includes a single or multiple outer resistive trace(s) 20, or even whether the display panel 60 includes the resistance detection circuitry 68 on-panel, the resistance(s) of the outer resistive trace(s) 20 can be used to determine whether a display panel has been properly cut and/or polished to within specified dimensions. A system 78 of FIG. 7, for example, may represent one manner of detecting whether a display panel 60 with at least one outer resistive trace 20 has been properly cut and/or polished to specified dimensions. In the system 78, the display panel 60 includes a single outer resistive trace 20 that has been cut and/or polished. Ideally, the display panel 60 will have been cut and/or polished precisely to certain specified dimensions (e.g., L×W) within a specified tolerance. If so, the resistance of the outer resistive trace 20 will have a resistance within a particular tolerance. If not, the display panel 60 has been cut or polished improperly—either too large or too small.

In the system 78 of FIG. 7, test circuitry 82 external to the display panel 80 uses probes 83 to measure a resistance of the outer resistive trace 20 of the display panel 80. In the example of FIG. 7, the probes 83 of the test circuitry 82 are placed at opposite ends of the outer resistive trace 20 to measure a total resistance of the outer resistive trace 20. In other examples, the probes 83 of the test circuitry 82 may be placed at alternative locations along the outer resistive trace 20 to measure the resistance of certain segments rather than the total resistance of the outer resistive trace 20. Although the system 78 illustrates a display panel 60 with a single outer resistive trace 20, any suitable configuration of outer resistive trace(s) 20 may be employed.

The test circuitry 82 may determine the resistance of the outer resistive trace 20 in any suitable manner. For example, the test circuitry 82 may be substantially the same as the resistance detection circuitry 68 discussed in this disclosure. In one example, the test circuitry 82 may be an ohmmeter. Since the system 78 uses the external test circuitry 82, the display panel 60 may or may not include the built-in resistance detection circuitry 68 discussed above.

The test circuitry 82 may provide an indication of the resistance to an operator or to a data processing system 84. The operator or the data processing system 84 may indicate whether the display panel 80 has been cut and/or polished to the specified dimensions based on the measured resistance of the outer resistive trace 20. The data processing system 84 may represent any suitable data processing circuitry (e.g., processor(s), memory, storage, and so forth) as generally discussed above with reference to the electronic device 10. Thus, the data processing system 84 may carry out instructions stored on machine-readable media in generally the same manner.

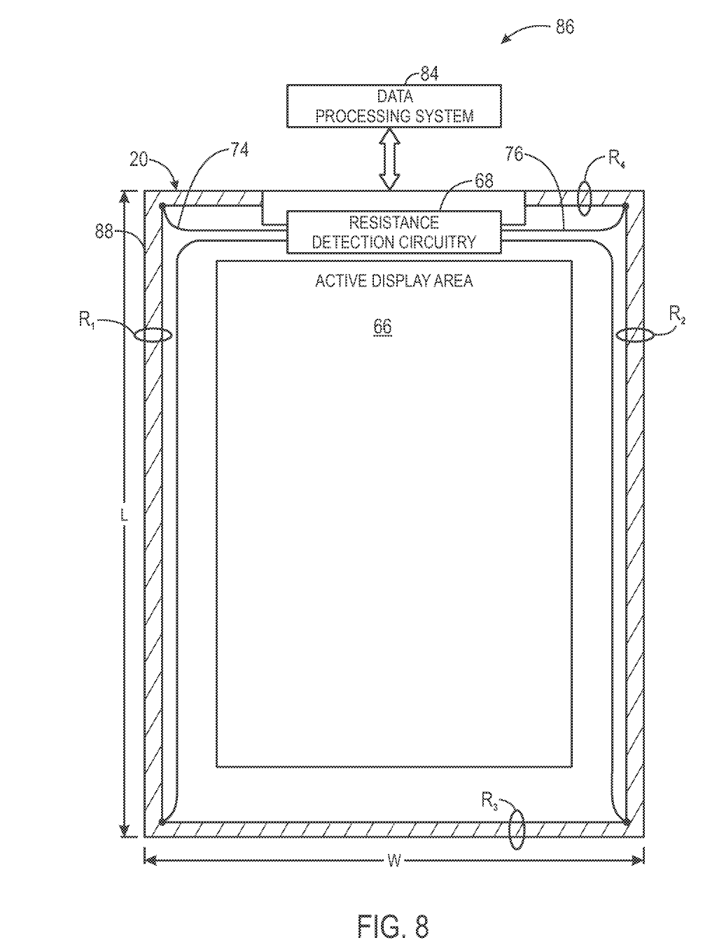

In a similar example, a system 86 of FIG. 8 may indicate whether a display panel 60 has been properly cut and/or polished using the resistance detection circuitry 68. The resistance detection circuitry 68 may provide the data processing system 84 an indication of the resistance of the outer resistive trace 20. For example, the resistance detection circuitry 68 may transmit one or more digital or analog values associated with the resistance(s) of the outer resistive trace(s) 20 to the data processing system 84. As in the example discussed above, the data processing system 84 may determine from the resistance(s) whether the display panel 60 has been cut and/or polished to within a tolerance of the specified dimensions (L×W).

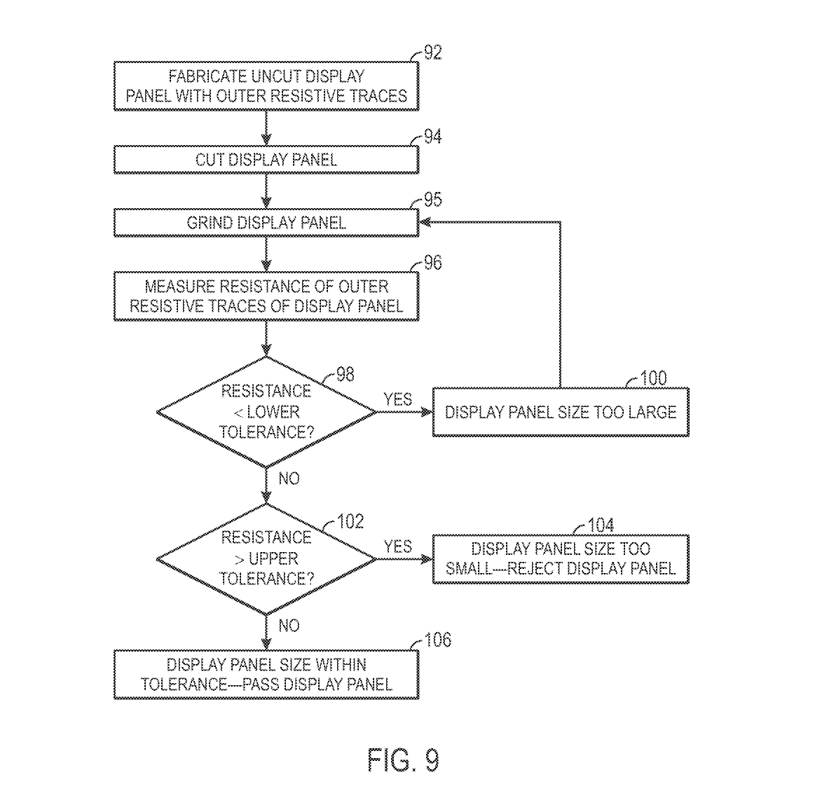

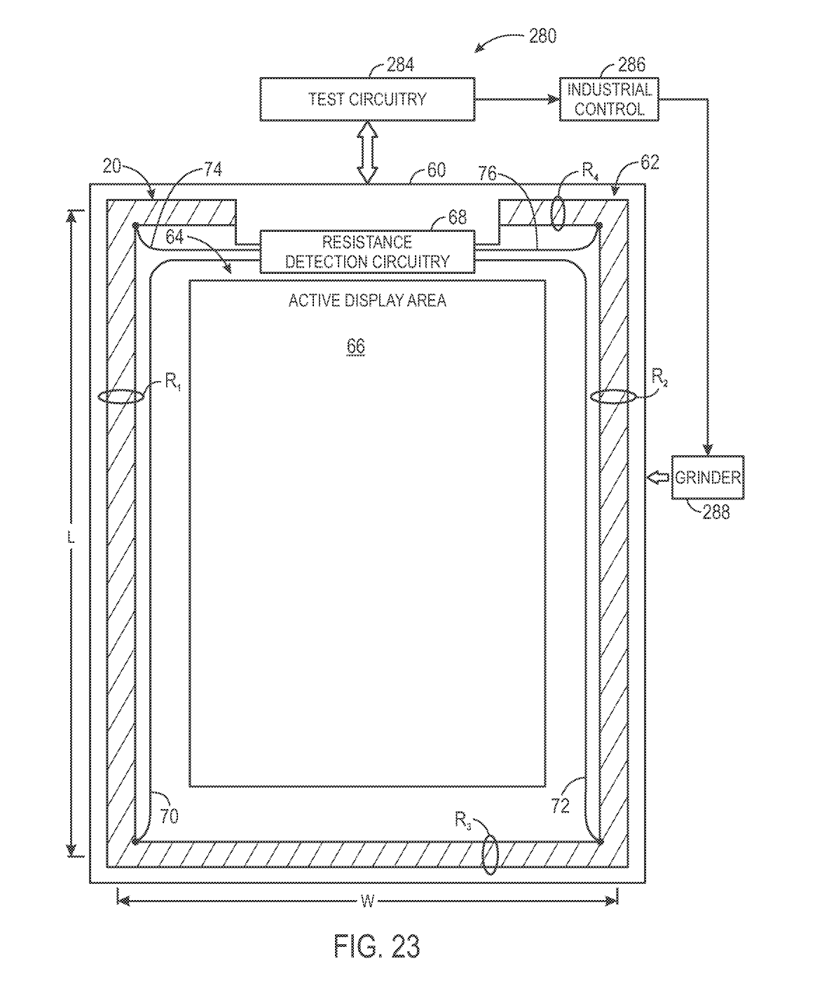

Using a system such as the system 78 of FIG. 7 or 86 of FIG. 8, a display panel 60 for a display 18 may be fabricated and tested to ensure it remains within specified dimensions. One example of a method for fabricating a properly dimensioned display panel 60 appears as a flowchart 90 of FIG. 9. The flowchart 90 of FIG. 9 may be carried out in part by automated processes and operations by the data processing circuitry 84 and/or by one or more human operators. The flowchart 90 may begin when a wafer of display panels may be fabricated, each display panel including outer resistive trace(s) disposed at least partly in the dead zone 62 of each display panel (block 92). An uncut display panel may be cut and/or polished according to any suitable techniques (blocks 94 and 95). The display panels may be cut and/or polished according to conventional methods or according to the techniques disclosed below with reference to FIGS. 23-28. In some embodiments, the display panels 60 may be cut only and not polished, omitting the actions of block 95.

Having cut and/or polished the display panel, the display panel may be tested to ensure the display panels have been properly cut and/or polished. To do so, the resistance of the outer resistive trace(s) of the display panel 60 may be ascertained (block 96). Ascertaining the resistance of the outer resistive traces 20 of the display panel may involve measuring or otherwise detecting an indication of the resistance of the outer resistive traces 20 using the test circuitry 82 and/or the resistance detection circuitry 68. When the resistance is determined to be less than a lower tolerance (block 98), it may be understood that the display panel 60 is too large (block 100). The display panel 60 then may be reground (block 95) if appropriate, such that the display panel 60 will be the proper size. Regrinding the display panel 60 may involve taking measures to ensure the various segments of the outer resistive traces 20 (e.g., R₁ and R₂) are properly proportioned. If grinding and/or regrinding is not an option, a display panel 60 determined to be too large at block 100 may instead be rejected.

If the resistance of the outer resistive trace(s) 20 is not below the lower tolerance (decision block 98), but rather is above an upper tolerance (decision block 102), the display panel 60 may be too small (block 104). Since a display panel 60 that has been ground to too small a size cannot be made to be larger, the display panel 60 may be rejected. If the resistance is above the lower tolerance (decision block 98) and beneath the upper tolerance (block 102), the display panel 60 may be understood to be within the tolerance (block 106). As such, the data processing circuitry 84 and/or an operator may indicate that the display panel 60 should be passed and used in the electronic display 18.

As generally noted above, it should be appreciated that the method discussed with reference to FIG. 9 may also generally apply to other patterned devices, such as a touch sensor panel (e.g., a single-sided indium tin oxide (SITO) or double-sided indium tin oxide (DITO) touch sensor panel), a flexible printed circuit (FPC), a printed circuit board (PCB), or any other suitable patterned device. Indeed, a touch sensor panel with outer resistive trace(s) may be processed in a substantially identical fashion. With regard to non-glass patterned devices such as FPCs or PCBs, polishing or grinding may not take place. Rather, FPCs or PCBs with outer resistive trace(s) may be die-punched or drilled out, as appropriate, and cut or recut to more proper size, if possible, in the manner generally outlined by the flowchart 90 of FIG. 9. The specific manner of cutting a touch sensor panel, FPC, or PCB to size is not the subject of the present disclosure—any suitable manner of cutting may be employed. Thus, as used herein, the term “cutting” refers to any suitable manner of cutting a touch sensor panel, FPC, or PCB to size, and may include breaking, slicing, die-punching, drilling, or any other suitable technique.

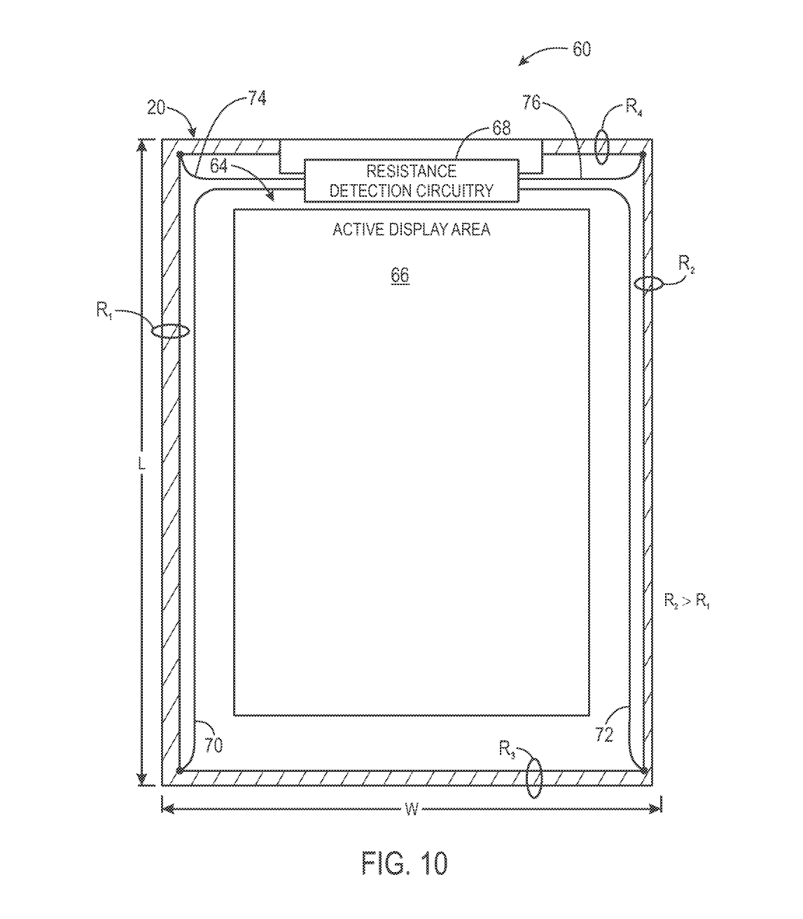

Even if the display panel 60 has the right length (L) and width (W) measurements, it is possible that the active display area 66 may not be located the proper distance from each edge. Still, improper proportions of the display panel 60 can be detected by measuring the resistance of the outer resistive trace(s) 20. For example, FIG. 10 shows a display panel 60 that has been ground too much on its right side, but ground too little on its left side. As such, the active display area 66 is slightly to the right of its proper location. Ideally, the active display area 66 of each display panel 60 will be located a specific distance from each edge of the display panel 60.

As can be seen in FIG. 10, the relatively wider geometry of the segment of the outer resistive trace(s) 20 on the left side of the display panel 60 results in a lower resistance R₁ across that segment. Likewise, the relatively thinner geometry of the segment on the right side of the display panel 60 results in a relatively higher resistance R₂ across that segment. By measuring the differences in resistance between the left segment (R₁) and the right segment (R₂), it may become apparent that the edges of the display panel 60 have not been properly ground. To discover such a discrepancy, the resistance detection circuitry 68 may detect the absolute resistances of the segments R₁ and R₂ or merely the relative resistances of R₁ and R₂. In some embodiments, it may become apparent that the display panel 60 proportions are erroneous when R₁≠R₂.

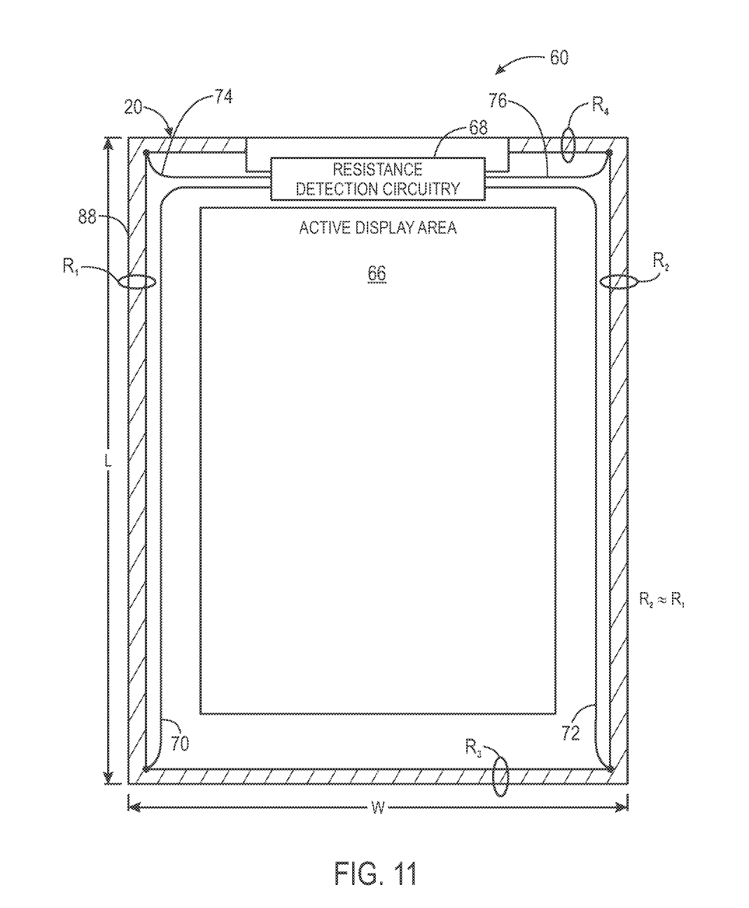

When the display panel 60 has been properly cut and/or polished, as generally illustrated in FIG. 11, the geometries of the outer resistive trace(s) 20 may result in resistances that are relatively constant. Under such conditions in some embodiments, the segment of the outer resistive trace(s) 20 on the left side (R₁) may be approximately equal to the segment of the outer resistive trace(s) 20 on the right side (R₂). That is, the display panel 60 proportions may be correct when R₁=R₂.

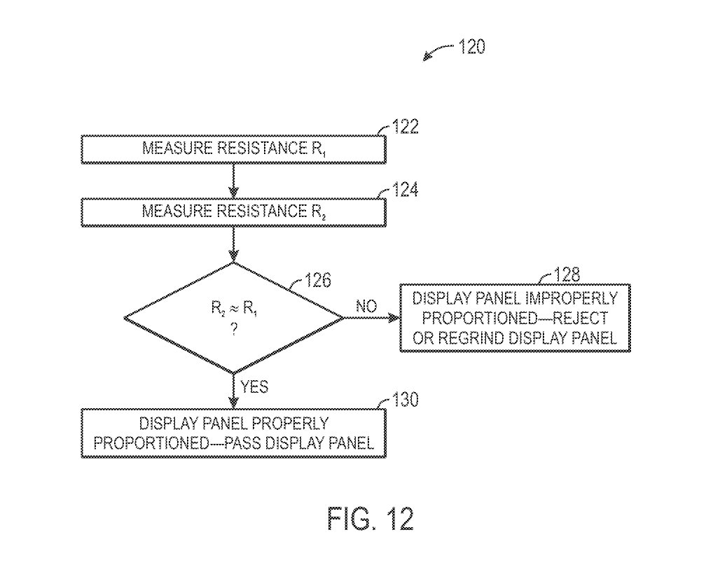

Accordingly, as shown by a flowchart 120 of FIG. 12, determining whether a display panel 60 has been properly proportioned may involve comparing the resistance of different segments of the outer resistive trace(s) 20. For example, the resistance of one segment of the outer resistive trace(s) 20 may be measured (block 122), another segment of the outer resistive trace(s) 20 on an opposite side of the display panel 60 may be measured (block 124), and these resistance values may be compared (decision block 126). The outer resistive trace(s) 20 of the display panel 60 may have been patterned such that the resistance of segments of the outer resistive trace(s) 20 will be equal when the display panel 60 has been properly cut and/or polished.

When the resistance of the first segment of the outer resistive trace(s) 20 (e.g., R₁) is not approximately equal to the segment of the outer resistive trace(s) 20 on an opposite side of the display panel 60 (e.g., R₂) (decision block 126), the display panel may be understood to be improperly proportioned (block 128). Thus, an operator or the data processing circuitry 84 may indicate that the display panel 60 should be rejected or reground, if possible. Otherwise, the display panel 60 may be understood to have been cut and/or polished to proper proportions (block 130). As such, an operator or the data processing circuitry 84 may indicate that the display panel 60 should be passed.

As discussed above with reference to FIGS. 38 and 39, the resistance detection circuitry 68 may include a Wheatstone bridge circuit to detect one or more of the resistances R₁, R₂, R₃, and R₄. In the examples of FIGS. 38 and 39, several known internal resistances Rᵢ₁, Rᵢ₂, and Rᵢ₃, and an unknown external resistance of R₁, R₂, R₃, and R₄, or some combination of these, may serve as bridging resistances between an internal resistance Rᵢ₄. Additionally or alternatively, the resistance detection circuitry 68 may employ a different Wheatstone bridge circuit configuration, as seen in FIG. 13 or 14. In contrast to the Wheatstone bridge circuits of FIGS. 38 and 39, the Wheatstone bridge circuits of FIGS. 13 and 14 may not necessarily enable the specific detection of any of the resistances R₁, R₂, R₃, or R₄. Rather, the Wheatstone bridge circuits of FIGS. 13 and 14 may enable the detection of a proportional relationship between these resistances.

Turning to the example of FIG. 13, a circuit diagram 150 illustrates a Wheatstone bridge that uses the resistances R₁, R₂, R₃, and R₄ as bridging resistances around an internal resistance Rᵢ. Though the internal resistance Rᵢ may be known, the resistances of the segments of the outer resistive trace(s) 20 (e.g., R₁, R₂, R₃, and R₄) may be unknown, having been ground down to a different value than originally patterned. Likewise, in the example of FIG. 14, a circuit diagram 160 illustrating a Wheatstone bridge circuit with bridging resistances formed by multiple outer resistive traces 20. Each of the traces of a segment of the outer resistive traces 20 is connected in parallel (e.g., in the manner of FIG. 5). Thus, the total resistance of each segment shown in FIG. 14 may be understood to represent a value of R₁, R₂, R₃, and R₄.

In particular, the circuit diagrams 150 of FIGS. 13 and 160 of FIG. 14 represent circuits that can indicate a relationship

$$\frac{{R}_{1}}{{R}_{3}} = \frac{{R}_{4}}{{R}_{2}}$$

when the voltage between R₁ and R₃ and the voltage between R₄ and R₂ are equal. Any deviation from this relationship can be used to determine the proportions

$$\frac{{R}_{1}}{{R}_{3}}$$

relative to

$$\frac{{R}_{4}}{{R}_{2}} .$$

With specific reference to FIG. 13, the circuit diagram 150 includes driver contacts DRV1 and DRV2, across test power (e.g., a known voltage or current) may be applied. The driver contact DRV1 generally may couple to an electrical node at the point 74 between R₁ and R₄, which represents a corner of the outer resistive trace(s) 20 of the display panel 60. The driver contact DRV2 may connect to an electrical node at the point 72 between R₃ and R₂, or the opposite corner of the outer resistive trace(s) 20 of the display panel 60. Sense contacts SENSE1 and SENSE2 may be disposed on opposite sides of the internal resistance Rᵢ. The sense contact SENSE1 couples to an electrical node at the point 70, while the sense contact SENSE2 couples to an electrical node at the point 76. The node at point 70 represents a point between the resistances R₁ and R₃, or a third corner of the outer resistive trace(s) 20 of the display panel 60. The node at point 76 is disposed between the resistances R₂ and R₄, or the opposite corner of the outer resistive trace(s) 20 of the display panel 60 from the node at the point 70.

The circuit diagram 160 of FIG. 14 is substantially similar, except that the resistances between the nodes 74, 70, 72, and 76 are several resistive segments in parallel. These resistive segments in parallel represent the multiple outer resistive trace(s) 20 that may be connected in parallel as generally illustrated in FIG. 5. That is, when four outer resistive traces are initially patterned onto the display panel 60, but one of the outer resistive trace(s) is ground away on all four sides, the outer resistive trace(s) may include 3 resistances connected in parallel between each of the nodes 70, 72, 76, and 74. For instance, the resistance between the nodes 70 and 74 may be the value of the resistances R_{1,3}, R_{1,2}, and R_{1,1} form a single parallel resistance. Likewise, between the node 70 and 72, the resistances R_{3,3}, R_{3,2}, and R_{3,1} form a single parallel resistance, between the node 72 and 76 the resistances R_{2,3}, R_{2,2}, and R_{2,1} form a single parallel resistance, and between the nodes 74 and 76, the resistances R_{4,3}, R_{4,2}, and R_{4,1} form a single parallel resistance. In the example of FIG. 14, the resistances R_{1,4}, R_{2,4}, R_{3,4}, and R_{4,4} are illustrated as having been ground away.

Power may be applied across the driving contact DRV1 and DRV2, and the resulting voltages at nodes 70 and 76 sensed by the sense contact SENSE1 and SENSE2. In some embodiments, the driving contact DRV1 and DRV2 and sense contact SENSE1 and SENSE2 may be contact accessible to probes on the display panel 60. In other embodiments, these contacts may be connected to internal circuitry of the resistance detection circuitry 68. It should be appreciated that, when power is applied across the driving contacts DRV1 and DRV2, the voltages that arise at the sense contacts SENSE1 and SENSE2 relate to the relationship of the resistances R₁, R₂, R₃, and R₄. Specifically, as mentioned above, the voltage at SENSE1 (V_{SENSE1}) relates to the voltage at SENSE2 (V_{SENSE2}) in the same way that

$$\frac{{R}_{1}}{{R}_{3}}$$

relates to

$$\frac{{R}_{4}}{{R}_{2}} .$$

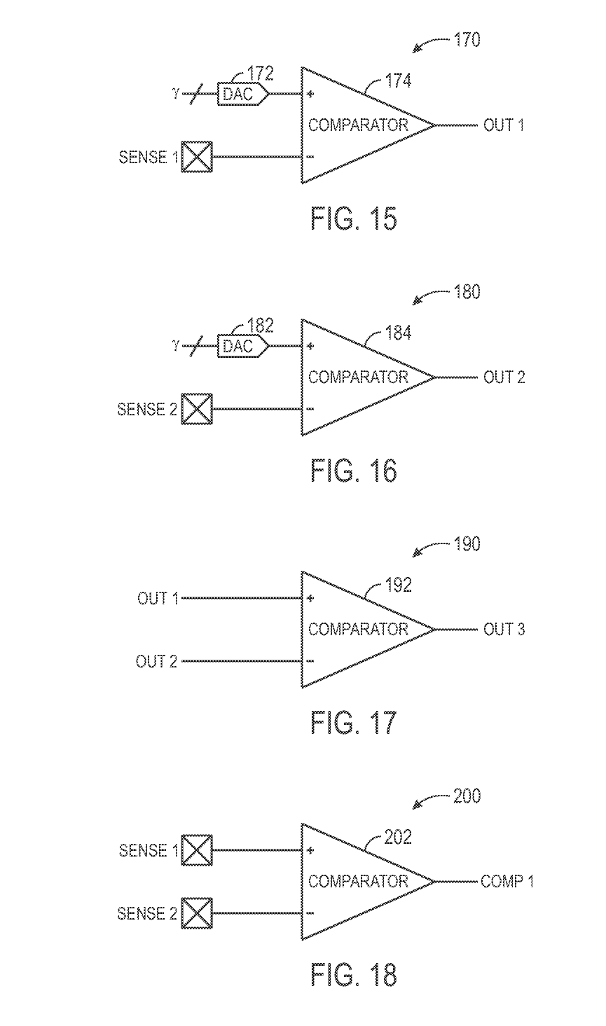

The resistance detection circuitry 68 may employ circuitry commonly available on a display panel 60 to determine the proportions of the resistances R₁, R₂, R₃, and R₄ relative to one another. Indeed, FIGS. 15-18 represent circuitry configurations that may be employed by the resistance detection circuitry 68 to determine the relationship of the resistances R₁, R₂, R₃, and R₄. For example, turning to FIG. 15, a circuit diagram 170 illustrates a circuit that can be used to determine a voltage value sense at the SENSE1 sense contact. In particular, a digital value γ may be supplied to a digital-to-analog converter (DAC) 172. The analog value output by the DAC 172 may enter a first input of a comparator 174 (e.g., a positive input). The voltage from the SENSE1 contact may be supplied to another input (e.g., a negative input) of the comparator 174. The resulting output signal, here shown as OUT1, relates the two values. When the digital value γ is chosen such that OUT1 is as close as possible to zero, the digital value γ may be understood to correspond to the sense voltage value at the SENSE1 contact. That is, the value OUT1 may be monitored while the digital value γ is varied until the value OUT1 is substantially zero. The digital value γ then may be understood to be a digital representation of the analog value of the SENSE1 voltage.

Similarly, as shown in FIG. 16 the digital value γ also may be used to determine a value of the voltage at the SENSE2 contact. As shown by a circuit diagram 180, the digital value γ may be supplied to a digital-to-analog converter 182, the output of which may enter an input (e.g., a positive input) of a comparator 184. The voltage at the SENSE2 contact may be supplied to another input (e.g., a negative input) of the comparator 184. The resulting output signal OUT2 represents a difference between the analog voltage of the SENSE2 contact and the analog value of the digital value γ. When the digital value γ is chosen such that OUT2 is as close as possible to zero, the digital value γ may be understood to correspond to the sense voltage value at the SENSE2 contact. That is, the value OUT2 may be monitored while the digital value γ is varied until the value OUT2 is substantially zero. The digital value γ then may be understood to be a digital representation of the analog value of the SENSE1 voltage.

In some embodiments, the resistance detection circuitry 68 may supply a given digital value γ to both of the circuits 170 and 180 to produce output values OUT1 and OUT2. The values OUT1 and OUT2 may be output by the resistance detection circuitry 68 (e.g., to the data processing system 84) or may be further compared by the resistance detection circuitry 68. As shown in a circuit 190 of FIG. 17, the output values OUT1 and OUT2 may enter different inputs of a comparator 192. The resulting output value OUT3 may indicate whether and to what degree the sense voltage values at the SENSE1 contact and the SENSE2 contact different from one another. This difference also may indicate the relationship

$$\frac{{R}_{1}}{{R}_{3}}$$

to

$$\frac{{R}_{4}}{{R}_{2}}$$

when used in combination with the Wheatstone bridge circuits of FIG. 13 or 14. Likewise, this difference may enable the determination of R₁, R₂, R₃, or R₄, or a combination of these, when used in combination with the Wheatstone bridge circuits of FIG. 38 or 39.

In some embodiments, the relationship between the SENSE1 voltage value and the SENSE2 voltage may be determined in an analog fashion, as generally illustrated by a circuit 200 of FIG. 18. In FIG. 18, the SENSE1 voltage value and the SENSE2 voltage value enter different inputs of a comparator 202. The output value of the comparator 202, here illustrated as COMP1, represents the analog difference between the SENSE1 voltage and the SENSE2 voltage.

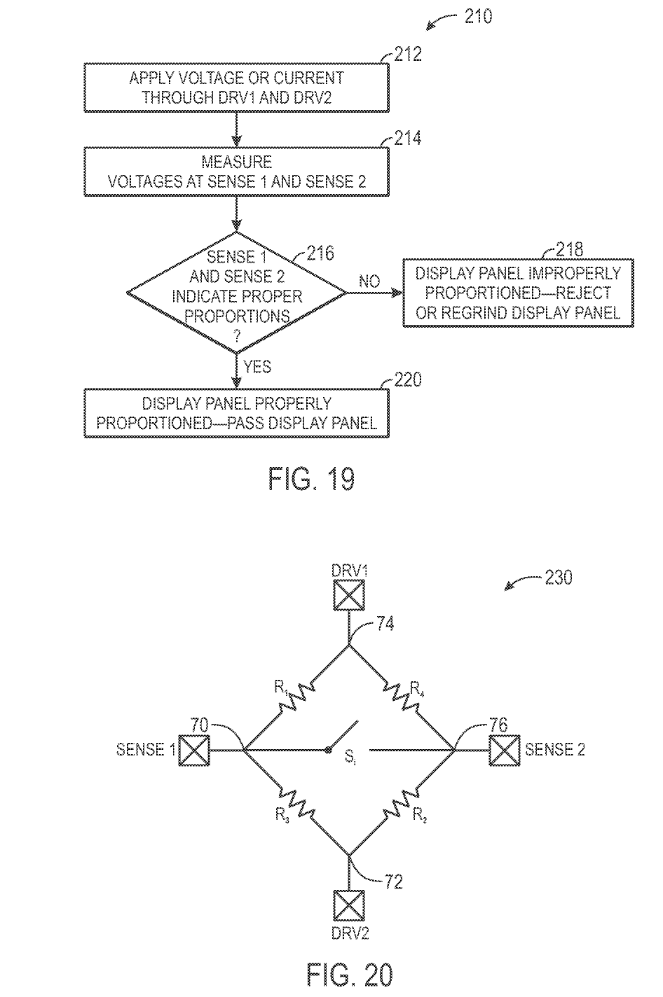

Using the Wheatstone bridge circuits of FIG. 13 or 14, the differences between the SENSE1 voltage and the SENSE2 voltage may indicate the proportions of the resistances R₁, R₂, R₃, and R₄. These proportions may indicate whether the display panel 60 has been cut and/or polished to proper proportions, as illustrated by a flowchart 210 of FIG. 19.

The flowchart 210 may begin when a voltage or current is applied through the driver contacts DRV1 and DRV2 (block 212). As mentioned above, the voltage or current may be applied internally (e.g., using circuitry commonly found in the driver circuitry of a display panel 60) or may be supplied by an external source (e.g., probes). As the voltage or current is being applied, the resulting voltages at the SENSE1 and SENSE2 contacts may be measured (block 214). In a similar manner, the resistance detection circuitry 68 may measure the voltages at the SENSE1 and SENSE2 contacts using the circuitry described above with reference to FIGS. 15-18. Additionally or alternatively, the test circuitry 82 external to the display panel 60 may employ any suitable manner of detecting these voltages.

When the values of the SENSE1 and SENSE2 voltages compare to one another according to a particular proportion, it may be understood that the display panel has been properly or improperly cut and/or polished. For example, the resistance values R₁, R₂, R₃, and R₄ of the segments of the outer resistive trace(s) 20 may be patterned such that, when the display panel 60 has been properly cut and/or polished, R₁=R₂=R₃=R₄. Under such conditions, the voltages at the SENSE1 and SENSE2 contact should be equal when the display panel 60 has been properly cut and/or polished. Alternatively, the outer resistive trace(s) 20 may be patterned such that, when the display panel 60 is properly cut and/or polished, the relationship between the resistances R₁, R₂, R₃, and R₄ takes any other suitable form.

In any case, if the relationship between the SENSE1 voltage and the SENSE2 voltage indicates the display panel 60 has not been properly cut and/or polished (decision block 216), the display panel 60 may be rejected or, if possible, reground (block 218). Otherwise, if the SENSE1 and SENSE2 voltages indicate that the display panel 60 has been properly cut and/or polished, the display panel 60 may be considered to have passed (block 220).

An alternative circuit 230, illustrated in FIG. 20, may be used to ascertain all four resistances R₁, R₂, R₃, and R₄ of the segments of the outer resistive trace(s) 20 of a display panel 60. The circuit 230 similarly includes the nodes 70, 72, 74, and 76, but the internal resistance Rᵢ is replaced by a switch Sᵢ. By way of example, the switch Sᵢ may be any suitable transistor. The circuit 230 may be formed in the resistance detection circuitry 68 or in some other circuitry external to the display panel 68.

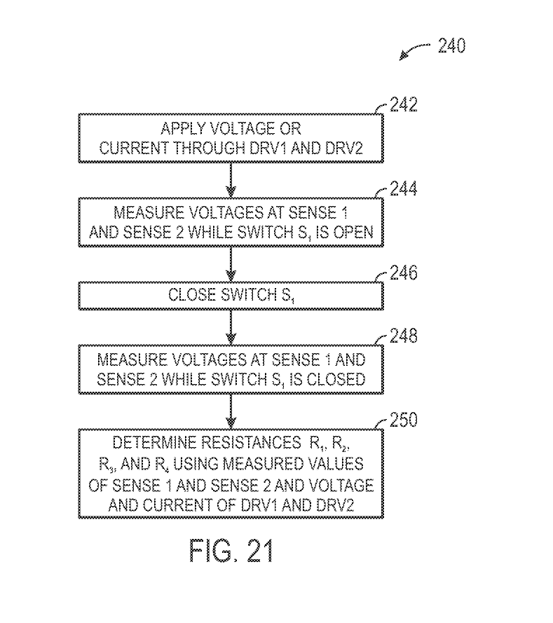

As illustrated by a flowchart 240 of FIG. 21, the circuit 230 may be used to determine the resistance values R₁, R₂, R₃, and R₄. Specifically, a voltage or current may be supplied across the driver contacts DRV1 and DRV2 (block 242). The voltages may be measured at the SENSE1 and SENSE2 contacts while the switch S₁ is open (block 244). The switch S₁ may be closed (block 246) and the voltages at the SENSE1 and SENSE2 contacts measured again while the switch S₁ is closed (block 248). It may be appreciated that while the switch S₁ is closed, the voltages at the SENSE1 and SENSE2 contacts should be the same. Using the measured voltages at SENSE1 and SENSE2, as well as the known values of voltage and current flowing through the driver contacts DRV1 and DRV2, the resistance values R₁, R₂, R₃, and R₄ can be determined using any suitable computation (e.g., nodal analysis). Such a calculation may be performed, for example, using the data processing circuitry 84 after the data processing circuitry 84 has received the measured values from the resistance detection circuitry 68.

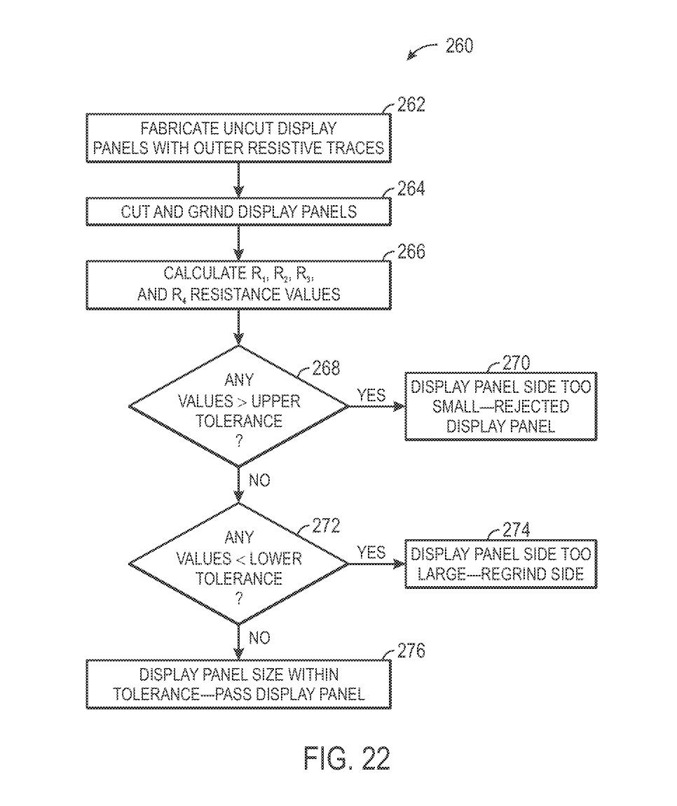

The display panel 60 size can be tested using this complete determination of the resistances R₁, R₂, R₃, and R₄, as seen in a flowchart 260 of FIG. 22. The flowchart 260 of FIG. 22 may be carried out in part by automated processes and operations by the data processing circuitry 84 and/or by one or more human operators. The flowchart 260 may begin when a wafer of display panels may be fabricated, each display panel including outer resistive trace(s) disposed at least partly in the dead zone 62 of each display panel (block 262). The uncut display panels may be cut and/or polished according to any suitable techniques (block 264). For example, the display panels may be cut and/or polished according to conventional methods or according to the techniques disclosed below with reference to FIGS. 23-28.

Having cut and/or polished the display panels, each of the display panels 60 may be tested to ensure the display panels 60 have been properly cut and/or polished. To do so, the resistance of the outer resistive trace(s) of the display panels 60 may be ascertained (block 266). Ascertaining the resistance of the outer resistive traces 20 of the display panel may involve measuring or otherwise detecting an indication of the resistance of the outer resistive traces 20 using the test circuitry 82 and/or the resistance detection circuitry 68. That is, the resistances R₁, R₂, R₃, and R₄ may be determined using the circuit of FIG. 20 and the method of FIG. 22. When the resistance of any of the resistances R₁, R₂, R₃, or R₄ is determined to be less than a lower tolerance (block 268), it may be understood that the display panel 60 is too large (block 270). The display panel 60 may be reground if appropriate, such that the display panel 60 will become the proper size. Regrinding the display panel 60 may involve taking measures to ensure the various segments of the outer resistive traces 20 (e.g., R₁ and R₂) are properly proportioned.

If none of the resistances R₁, R₂, R₃, and R₄ of the outer resistive trace(s) 20 is below the lower tolerance (decision block 268), but at least one is above an upper tolerance (decision block 272), the display panel 60 may be too small (block 274). Since a display panel 60 that has been ground to too small a size cannot be made to be larger, the display panel 60 may be rejected. If the resistance is above the lower tolerance (decision block 268) and beneath the upper tolerance (block 272), the display panel 60 may be understood to be within the tolerance (block 276). As such, the data processing circuitry 84 and/or an operator may indicate that the display panel 60 should be passed and used in the electronic display 18.

In the examples above, the outer resistive trace(s) 20 were used to determine whether the display panel 60 or other patterned device had been cut and/or polished to specified dimensions. The outer resistive trace(s) 20 of a display panel 60 may also be used to properly cut and/or grind the display panel 60 to such specified dimensions in the first place. For example, a system 280 of FIG. 23 can be used to grind the display panel 60 to a specified amount based on the resistance of segments of the outer resistive trace(s) 20. In the example of FIG. 23, a display panel 60 or another patterned device having outer resistive trace(s) 20 is coupled to test circuitry 284. The test circuitry 284 may be configured to receive digital values of resistance or other values indicative of the resistance of the entire outer resistive trace(s) 20 or of certain segments of the outer resistive trace(s) 20 from the resistance detection circuitry 68 (e.g., in the manner of FIG. 8). Additionally or alternatively, the test circuitry 284 may obtain an indication of the resistance of the outer resistive trace(s) 20 using, for example, probes disposed on the outer resistive trace(s) 20 (e.g., in the manner of FIG. 7).

The test circuitry 284 may provide the value of the resistance to industrial control circuitry 286. It should be understood that the industrial control circuitry 286 may represent any suitable data processing circuitry (e.g., processor(s), memory, and so forth) that can control a grinder 288 based on the resistance determined by the test circuitry 284. That is, as will be described below, the industrial control circuitry 286 may control the grinder 288 to grind away edges of the display panel 60 until the resistance of the outer resistive trace(s) 20 and/or a segment of the outer resistive trace(s) 20 reaches specified values or proportions. In addition to, or in lieu of, the grinder 288, a cutting device may be employed to successively cut away slices of the display panel 60 or other patterned device.

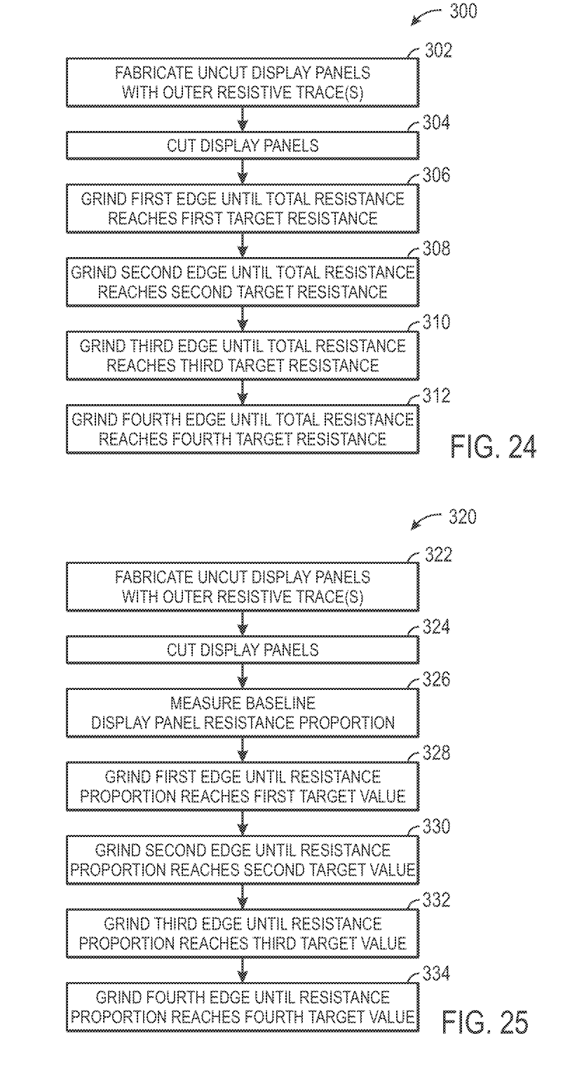

For example, as illustrated by a flowchart 300 of FIG. 24, the system 280 may be used to cut or grind a display panel 60 or other patterned device to specified dimensions based on a measurement of the entire resistance of the outer resistive trace(s) 20. The flowchart 300 may begin as the display panels 60 are formed and patterned with outer resistive trace(s) 20 disposed near the edges of the display panel 60 (block 302). It may be appreciated that, in some embodiments, the outer resistive trace(s) 20 may be patterned at the same time as elements of the active display area 66 of the display panel 60. In so doing, the active display areas 66 of the display panels 60 may be located a constant distance from the outer resistive trace(s) 20. The display panels 60 may be cut into individual display panels 60 (block 304) before they are ground.

Grinding a display panel 60 may allow the dimensions of the display panel 60 to be relatively finely defined (e.g., to a tolerance smaller than around 300 μm, 250 μm, 200 μm, or 150 μm, or even smaller still). To more precisely grind the display panel 60 to desired specified dimensions, a first edge of the display panel 60 may be ground until the entire resistance of the outer resistive trace(s) 20 reaches a first target resistance (block 306). The first target resistance should be higher than the total resistance of the outer resistive trace(s) 20 before the outer resistive trace(s) 20 are ground. After grinding the first edge at block 306, the grinder 288 may grind a second edge of the display panel 60 until the total resistance of the outer resistive trace(s) 20 reaches a second target resistance (block 308). This second target resistance will be higher than the first target resistance because more of the outer resistive trace(s) 20 will have been ground away. Additionally or alternatively, the display panel 60 or other patterned device (e.g., touch sensor panel, FPC, PCB, etc.) may be successively cut away rather than grinded. That is, a cutting device may cut successively more of the display panel 60 or patterned device edge until the target resistances are substantially met. Although potentially less precise than grinding, cutting may be preferable to grinding for some patterned devices that may not contain glass (e.g., an FPC or a PCB).

The display panel 60 may continued to be ground in a similar way on other edges of the display panel 60. For example, the grinder 288 may grind a third edge of the display panel 60 until the total resistance of the outer resistive trace(s) 20 reaches a third target resistance (block 310), before grinding a fourth edge of the display panel 60 until the total resistance of the outer resistive trace(s) 20 reaches a fourth target resistance (block 312). As should be appreciated, the third target resistance may be higher than the first and second target resistances, and the fourth target resistance may be higher than the first, second, and third target resistances. If desired, the grinder 288 may continue to grind the outer edges in finer increments until finer target resistances have been reached.

Additionally or alternatively, the proportion of resistances of segments of the outer resistive trace(s) 20 can be used to indicate how much to grind away edges of the display panel 60. For example, a flowchart 320 of FIG. 25 represents a method in which the grinder 288 may grind away edges of the display panel 60 until certain target values of proportions of the resistance segments around the edges of the display panel 60 have been reached. The flowchart 320 may begin when display panels 60 are formed and patterned with outer resistive trace(s) 20 (block 322). As mentioned above, the outer resistive trace(s) 20 may be patterned at the same time as certain elements of the active display area 66 of the display panel 60. The display panels 60 may be cut apart into separate display panels 60 (block 324).

In some embodiments, before grinding the edges of the display panel 60, a baseline proportion of the resistances of the segments of the outer resistive trace(s) 20 may be measured (block 326). For example, a Wheatstone bridge circuit such as those described above with reference to FIG. 13 or 14 may be employed. The baseline output voltage values at the sense contacts SENSE1 and SENSE2 can be compared. In one example, the outer resistive trace(s) 20 may be patterned on the display 60 in such a way as to have segments of equal resistance before being ground (e.g., R₁=R₂=R₃=R₄). In such a case, the SENSE1 and SENSE2 voltages may be approximately equal. In other examples, the outer resistive trace(s) 20 may have other initial proportions. It should be appreciated that the baseline proportions may or may not be determined in every embodiment of the instant method. That is, the actions of block 326 may or may not be carried out in various embodiments.

Whether or not the baseline proportions of the display panel 60 are determined, the grinder 288 may grind a first edge of the display panel 60 until the proportion of the resistances R₁, R₂, R₃, and R₄ (e.g., the relative value of the SENSE1 and SENSE2 voltages) reaches a first target value (block 328). The first target value may represent a relationship between the resistances R₁, R₂, R₃, and R₄ that may occur when the first edge is ground down a proper amount. The first target value (as well as succeeding target values) may vary from display panel 60 to display panel 60 depending on the baseline proportions, if desired. It should be appreciated that grinding the first edge of the display panel 60 will entail grinding away at least part of a segment of the outer resistive trace(s), thereby changing the relationship between the resistance values R₁, R₂, R₃, and R₄.

This pattern may continue. That is, the grinder 288 may grind a second edge of the display panel 60 until the relationship between the segments of the outer resistive trace(s) 20 reach a second target value (block 330), grinding a third edge until a third target value is reached (block 332), and grinding a fourth edge until a fourth target value is reached (block 334). In certain embodiments, the edges of the display panel 60 may be ground down in a manner such that the second target value and the fourth target value are the same. For example, the second edge to be ground may be the opposite of the first, and the fourth edge to be ground may be the opposite of the third. Thus, if these opposite edges are ground equally and the initial, baseline proportion of the display panel 60 indicates equal resistances, grinding the second and fourth edges to the proper degree may cause the SENSE1 and SENSE2 voltages to be equal.

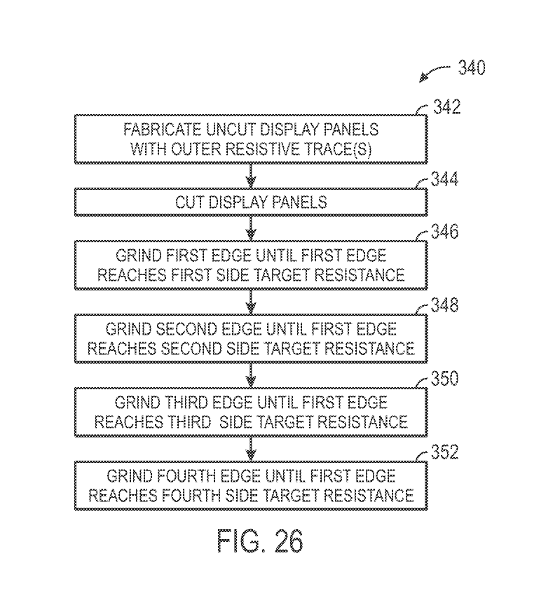

In another example, illustrated as a flowchart 340 of FIG. 26, the particular resistance of segments of the outer resistive trace(s) 20 at specific edges may be monitored. The flowchart 340 of FIG. 26 may begin as display panels 60 are formed and patterned with outer resistive trace(s) 20 disposed around the edges of the display panel 60 (block 342). As mentioned above, the outer resistive trace(s) 20 may be patterned at the same time as an element of the active area 66 is formed, to ensure the distance between the active area 66 and the outer resistive trace(s) 20 remains constant from batch to batch. The display panel 60 may be cut into individual display panel 60 (block 344) before being ground to more precise dimensions.

In the flowchart 340 of FIG. 26, the resistances of the segments of the outer resistive trace(s) 20 are measured or detected individually. That is, probes may be attached across only certain sides of the display panel 60 outer resistive trace(s) 20 as the grinder 288 grinds down that edge in some embodiments. In other embodiments, the resistance of individual segments of the outer resistive trace(s) 20 may be determined using the Wheatstone bridge circuits illustrated in FIG. 39 or via the circuit described above with reference to FIG. 20. While at least periodically measuring the resistance of a segment of the outer resistive trace(s) 20 near a first edge of the display panel 60, the grinder 288 may grind that first edge until a first edge target resistance has been reached (block 346). Likewise, the grinder 288 may grind a second edge of the display panel 60 until a second edge target resistance has been reached (block 348) the grinder 288 may grind a third edge until a third edge target resistance has been reached (block 350), and the grinder 288 may grind a fourth edge of the display panel 60 until a fourth edge target resistance has been reached (block 352). Having ground the display panel 60 until the outer resistive trace(s) 20 segment has these specific target resistances, the display panel 60 may be more likely to have been precisely cut and/or polished to the desired specified dimensions.

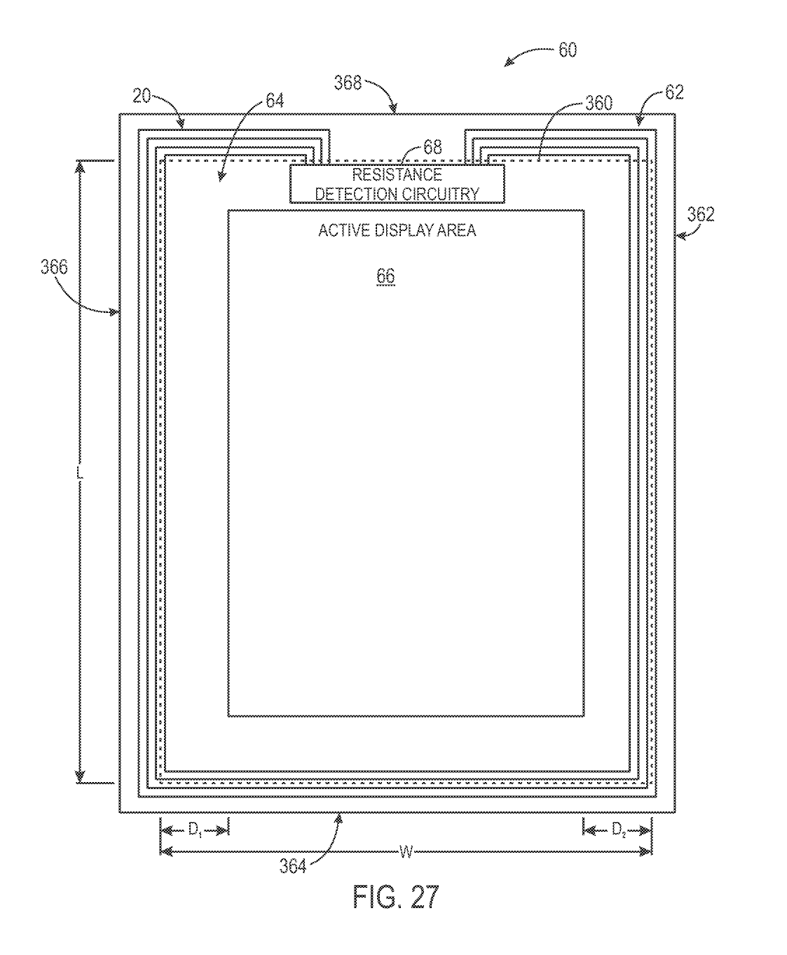

Alternatively, the grinder 288 may properly grind a display panel 60 to specified dimensions using multiple outer resistive trace(s) 20 patterned in a manner such as that shown in FIG. 27. Specifically, in the example of FIG. 27, the outer resistive trace(s) 20 are patterned through the dead zone 62 and the peripheral circuitry area 64 in such a way that for each edge, when properly ground, a different number of traces of the multiple outer resistive trace(s) 20 will remain. Indeed, a dashed line at numeral 360 defines the specified dimensions of the display panel 60 after being properly cut and/or polished. On a first edge 362 of the display panel 60, only one of the multiple outer resistive trace(s) 20 is located outside of the bounds of the specified dimension 360. Thus, the resistance detection circuitry 68 may detect that the first edge 362 of the display panel 60 of FIG. 27 has been properly ground after only the outermost one of the outer resistive trace(s) 20 has been ground away. Likewise, a second edge 364 of the display panel 60 may be understood to have been properly cut and/or polished when both the outermost and a second outermost of the outer resistive trace(s) 20 have been ground away. A third edge 366 may be understood to have been ground to the specified dimensions 360 when the three outermost edges have been cut and/or polished away, and a fourth edge 368 of the display panel 60 may be understood to have been cut and/or polished away to the specified dimensions 360 when all four of the illustrated outer resistive trace(s) 20 have been ground away.

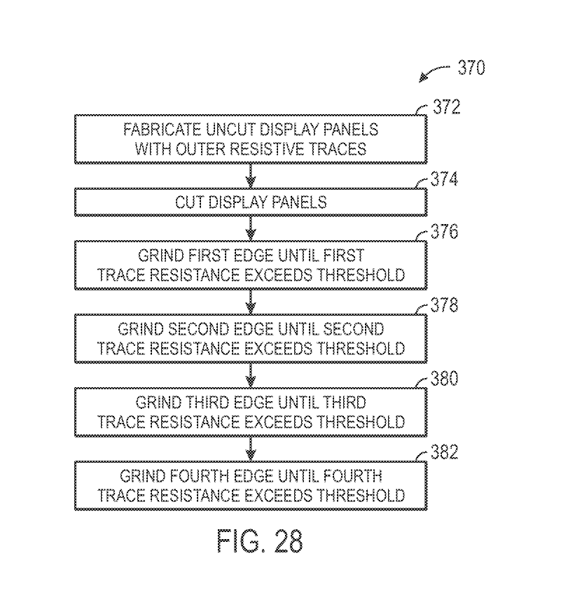

Using a display panel 60 having outer resistive trace(s) 20 patterned in a manner such as that shown in FIG. 27 with the system 280 of FIG. 23, a display panel 60 may be fabricated to the specified dimensions 360. One manner of doing so appears in a flowchart 370 of FIG. 28. The flowchart 370 may begin when a number of display panels 60 are formed and patterned with outer resistive trace(s) 20 generally patterned in a manner such as shown in FIG. 27 (block 372). The outer resistive trace(s) 20 may be patterned at the same time as an element of the active display area 66 to ensure the active display area 66 is located a particular distance from the outer edges of the specified dimensions 360. The display panel 60 may be cut into individual display panels 60 (block 374) before being ground to the specified dimensions 360.

In particular, the grinder 288 may grind the first edge 362 of the display panel 60 until the resistance detection circuitry 68 detects that the resistance of the outermost of the outer resistive trace(s) 20 has exceeded a threshold (block 376). For example, the threshold of the outermost trace of the multiple outer resistive trace(s) 20 may be above some value indicating an infinite resistance. An infinite resistance would signify that there has been a complete break in at least part of the first, outermost edge of the multiple resistive trace(s) 20. The grinder 288 then may grind the second edge 364 of the display panel 60 until both the first, outmost edge of the multiple outer resistive trace(s) 20 and a second, next-outermost of the multiple outer resistive trace(s) 20 has been ground away (block 378). It may be appreciated that the resistance detection circuitry 68 may not detect any changes in the first, outermost of the outer resistive trace(s) 20 as it is ground away on the second edge 364, since the resistance of this first, outermost trace of the multiple outer resistive trace(s) 20 will already be infinite when the second edge 364 is ground down. However, because grinding the first edge 362 did not involve grinding away any part of the second, next-outermost of the multiple outer resistive trace(s) 20, the resistance detection circuitry 68 may detect when the resistance of this second, next-outermost of the multiple outer resistive trace(s) 20 exceeds a threshold (e.g., becomes substantially infinite). When the second, next-outermost of the multiple outer resistive trace(s) 20 exceeds the threshold, signifying it has been ground away, the grinder 288 may be controlled to stop grinding the second edge.

This pattern may also continue. The grinder 288 may grind the third edge 366 of the display panel 60 until a third-outermost of the outer resistive trace(s) 20 is ground away (block 380). The grinder 288 next may grind the fourth edge 368 of the display panel 60 until the fourth-outermost of the outer resistive trace(s) 20 is ground away (block 382).

Outer resistive trace(s) 20 can also be used to monitor the integrity of a display panel 60. That is, the outer resistive trace(s) 20 may enable the detection of fractures or microfractures along edges of the display panel 60. The resistance and/or continuity of the outer resistive trace(s) 20 may change when a fracture or microfracture arises. For example, the resistance may increase along a segment of the outer resistive trace(s) 20 when a fracture or microfracture disrupts the continuity of the segment. By monitoring the outer resistive trace(s) 20 for such changes in resistance, likely fractures or microfractures may be detected.

For example, the resistance of some segment of the outer resistive trace(s) 20 may change resistance at a time other than while the display panel 60 is being ground. Such an unexpected change in resistance may indicate that a fracture or microfracture has interrupted the continuity of the outer resistive trace(s) 20. Though a microfracture may not immediately produce a catastrophic failure of the electronic display 18, it could signal the likely future occurrence of a catastrophic display 18 failure. Moreover, the extent and/or location of the occurrence of such microfractures could indicate whether the display panel 60 is likely to suffer a catastrophic failure at some point in the future, as well as indicate when a manufacturing failure is occurring.

Thus, by monitoring the outer resistive trace(s) 20, locations of fractures or microfractures may be detected. For example, the resistance of one segment of the outer resistive trace(s) 20 may quickly and unexpectedly increase in resistance. This increase in resistance may signal that the edge of the display panel 60 where the segment appears has been at least partially broken. Thus, when a fracture or microfracture occurs, which may produce a discontinuity near the edge of the display panel 60 that increases the resistance of the outer resistive trace(s) 20 at that point, the resistance detection circuitry 68 may be able to detect the change in resistance. By noting along which segment(s) the increase in resistance occurred, the location(s) of the likely fracture or microfracture in the display 60 can be determined.

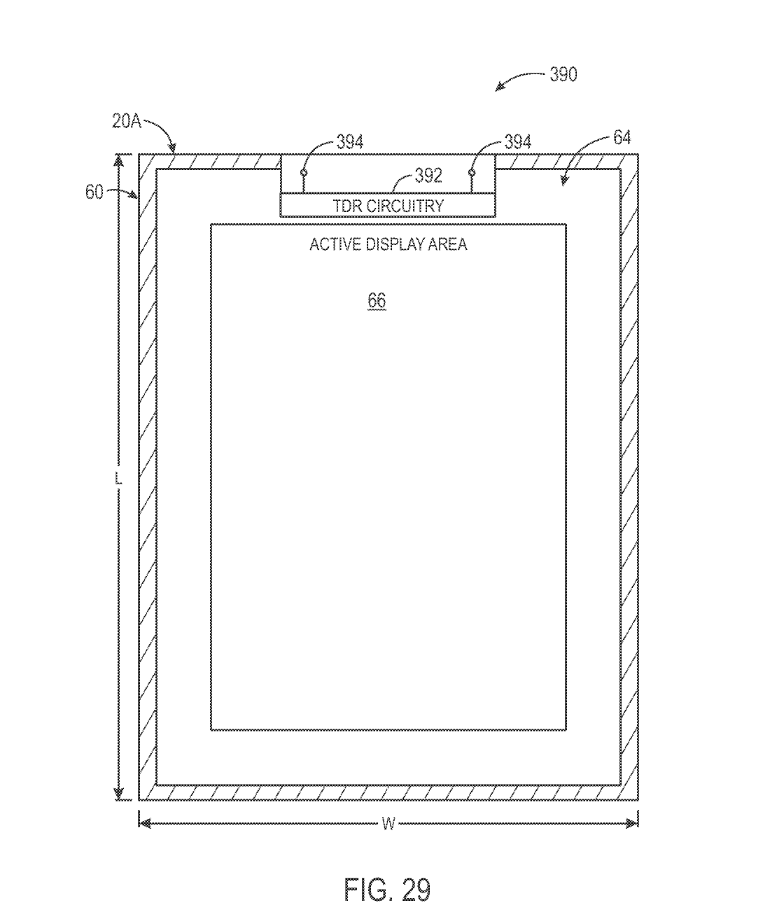

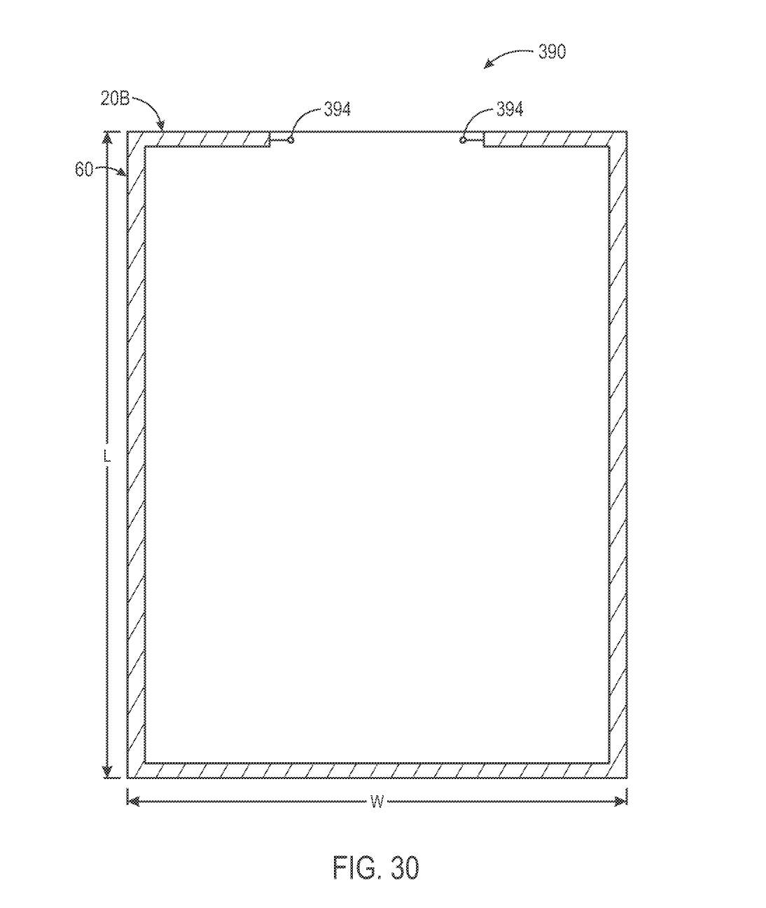

Additionally or alternatively, locations of fractures or microfractures may be identified through time domain reflectance (TDR), as generally illustrated by FIGS. 29 and 30. In FIGS. 29 and 30, a display panel 60 that employs a microfracture localization system 390 is illustrated. FIG. 29 represents a top side of the display panel 60 and FIG. 30 represents a bottom side of the display panel 60. The display panel 60 of FIGS. 29 and 30 includes time domain reflectance (TDR) circuitry 392 that is electrically connected to a top outer resistive trace 20A. The TDR circuitry 392 may also be electrically connected to a bottom outer resistive trace 20B through via holes 394. Additionally or alternatively, the TDR circuitry 392 may be electrically connected to the bottom outer resistive trace 20B using a flexible printed circuit (FPC) bonded to the bottom surface of the display panel 60. The TDR circuitry 392 may replace or may be used alongside the resistance detection circuitry 68—these two elements are not necessarily mutually exclusive. In alternative embodiments, the TDR circuitry 392 may be external from the display panel 60 (e.g., a component of external test circuitry).

The TDR circuitry 392 may apply an AC signal over the outer resistive trace(s) 20A and/or 20B. Discontinuities in the outer resistive trace(s) 20A and/or 20B may become apparent as portions of the AC signal are reflected back to the TDR circuitry 392. Thus, the TDR circuitry 392 may identify the location(s) where discontinuities in the outer resistive trace(s) 20A and/or 20B arrive. Although the outer resistive trace(s) 20 are illustrated as single top and bottom outer resistive traces in FIGS. 29 and 30, other configurations are contemplated. For example, only top outer resistive trace(s) 20A or only bottom outer resistive trace(s) 20B may appear on the display panel 60. Additionally or alternatively, the outer resistive trace(s) 20 may be patterned as stripline transmission lines to more easily identify discontinuities using time domain reflectance (TDR).

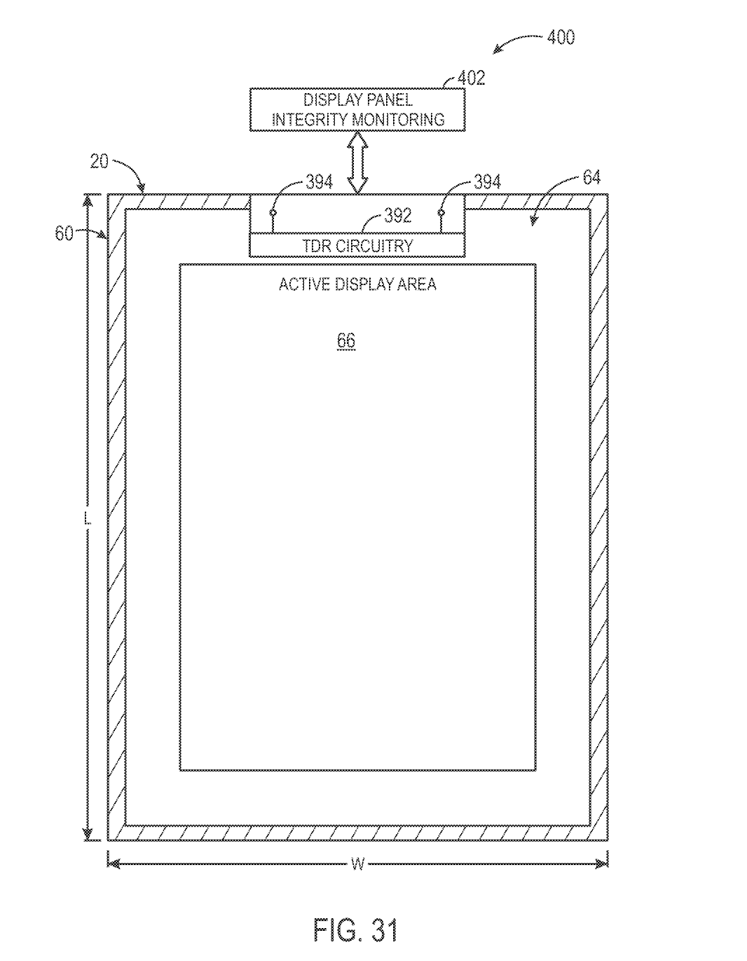

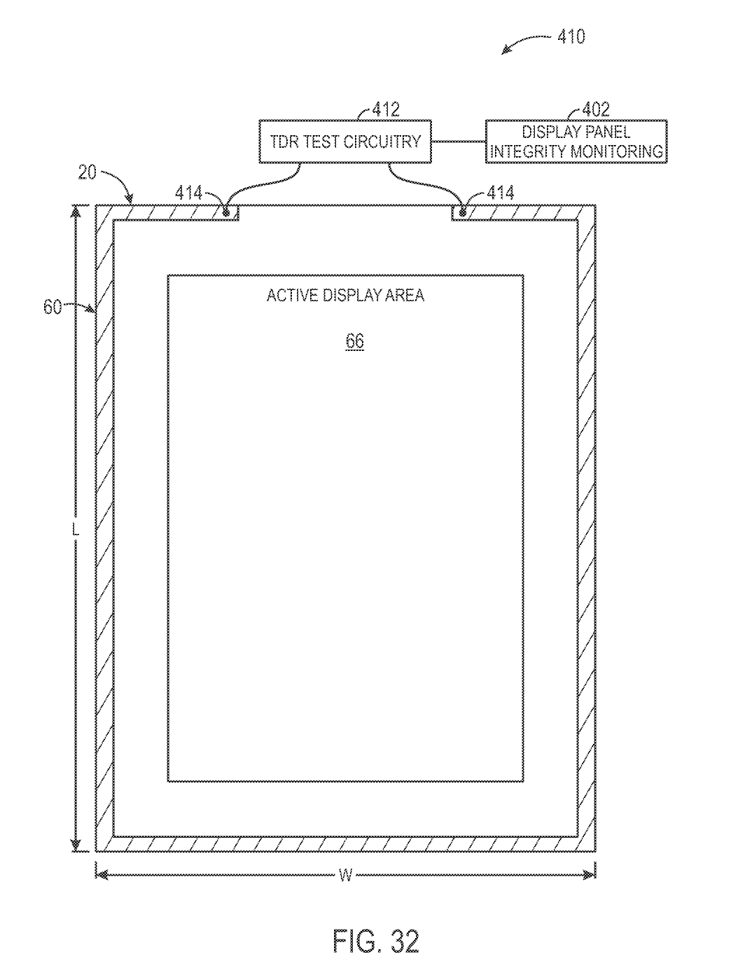

Time domain reflection (TDR) may allow a system 400, shown in FIG. 31, to detect the occurrence of microfractures in the display panel 60. As illustrated by the system 400, display panel integrity monitoring 402 may be in communication with the TDR circuitry 392. Additionally or alternatively, external TDR circuitry may be employed as illustrated by a system 410 of FIG. 32. The TDR circuitry 392 or external TDR circuitry may apply an AC signal over the outer resistive trace(s) 20 on a top side and/or a bottom side of the display panel 60. The TDR circuitry 392 then may provide an indication of location(s) where discontinuities are occurring. Additionally or alternatively, the display panel integrity monitoring 402 may obtain relatively raw data from the TDR circuitry 392, such as the location of discontinuities in the outer resistive traces 20 where parts of the AC signal has been reflected. From such relatively raw TDR data, the display panel integrity monitoring 402 may determine when and/or where discontinuities have occurred. These discontinuities may signal the location(s) and/or extents of fractures or microfractures along edges of the display panel 60.

Additionally or alternatively, the display panel 60 may not include the TDR circuitry 382 patterned on the display panel 60. Instead, in a system 410 shown in FIG. 32, time domain reflectance (TDR) test circuitry 412 located external to the display panel 60 may perform substantially the same time domain reflectance testing using probes 414 placed on the outer resistive trace(s) 20. The TDR test circuitry 412 may provide an indication of the location where microfractures may be occurring in the display panel 60 to the display panel integrity monitoring 402. It may be appreciated that the TDR test circuitry 412 and/or the display panel integrity monitoring 402 may include data processing circuitry that can run instructions stored in some form of memory (e.g., memory such as the memory 14 and/or storage such as the nonvolatile storage 16).

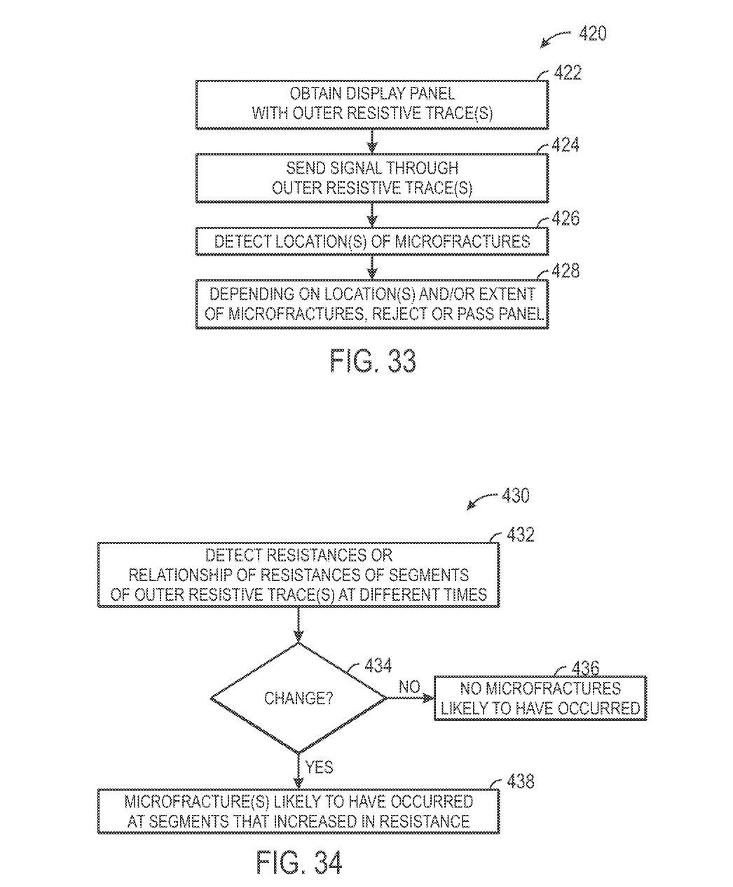

Quality control during the manufacture of the display panel 60 may be maintained by detecting the location and/or extent of microfractures in the display panel 60. For example, as illustrated by a flowchart 420 of FIG. 33, the system 400 or 410 may be used to reject or pass a display panel 60 depending on the locations or extent of detected microfractures through time domain reflectance (TDR). The flowchart 420 of FIG. 33 may be carried out as instructions used by the display panel integrity monitoring 402 and/or as an industrial control process carried out by human operators using test tools.

The flowchart 420 may begin when a display panel 60 having outer resistive trace(s) 20 is obtained and connected to display panel integrity monitoring 402 (block 422). The TDR circuitry 392 or TDR test circuitry 412 may transmit an AC signal through the outer resistive trace(s) 20 (block 424). Based on the amount of reflectance occurring when the signal is sent through the outer resistive trace(s) 20, the display panel integrity monitoring 402 may detect any location(s) of fractures or microfractures that may be found on the display panel 60 (block 426). Depending on the location(s) and/or the extent of the microfractures on the display panel 60, the display panel integrity monitoring 402 and/or a human operator may decide to reject or pass the display panel 60 (block 428). For example, the likelihood of catastrophic failure of the display panel 60 given the location(s) and/or extent of microfractures may be correlated to statistical experimental data and/or computer modeling data. Thus, whether the display panel 60 is permitted to be used in an electronic device 10 sold to a user may depend on the likelihood that, given the location(s) and/or extent of microfractures, the display panel 60 is unlikely to suffer a catastrophic failure due to these microfractures.

Systems that detect the resistance of different segments of the outer resistive trace(s) 20 may also be used to detect the location(s) and/or extent of fractures or microfractures along edges of a display panel 60. For example, a flowchart 430 of FIG. 34 illustrates a manner of detecting the location(s) and/or extent of fractures or microfractures by monitoring changes in resistance or proportions of resistances of segments of the outer resistive trace(s) 20. The flowchart 430 of FIG. 34 may be carried out, for example, using the systems illustrated in FIG. 7 or 8 or using similar systems. Data processing circuitry such as the data processing system 84 and/or display panel integrity monitoring 402, and/or human operators, may carry out the flowchart 430 of FIG. 34.

The flowchart 430 may begin when measurements of the resistance of segments of the outer resistive trace(s) 20 and/or a proportion of the resistance of the outer resistive trace(s) 20 are detected over at least two different times using any suitable technique (block 432). For example, the resistance of segments of the outer resistive trace(s) 20 may be measured using resistance detection circuitry 68 having circuitry such as that illustrated in FIG. 20, 38, or 39. Additionally or alternatively, the proportion of the resistances of segments of the outer resistive trace(s) 20 may be detected using resistance detection circuitry 68 having circuitry such as that illustrated in FIG. 13 or 14.

If the resistance of a segment of the outer resistive trace(s) 20 or the proportion of the resistance of the segments has changed over time, this change could be due to the occurrence of a fracture or microfracture. Thus, when no changes have occurred (decision block 434), data processing circuitry such as the data processing system 84, display panel integrity monitoring 402 (e.g., the processor(s) 12 of an electronic device 10), and/or human operators may identify that no fractures or microfractures are likely to have occurred (block 436). On the other hand, when changes have occurred (decision block 434), a fracture or microfracture may be deemed to have occurred (block 438). In such a case, the fracture or microfracture may be understood to have occurred at the segment of the outer resistive trace(s) 20 where resistance has changed. The segment may be identified based on a specific measurement of the resistance of the segment or from a change in the proportion of the resistances.

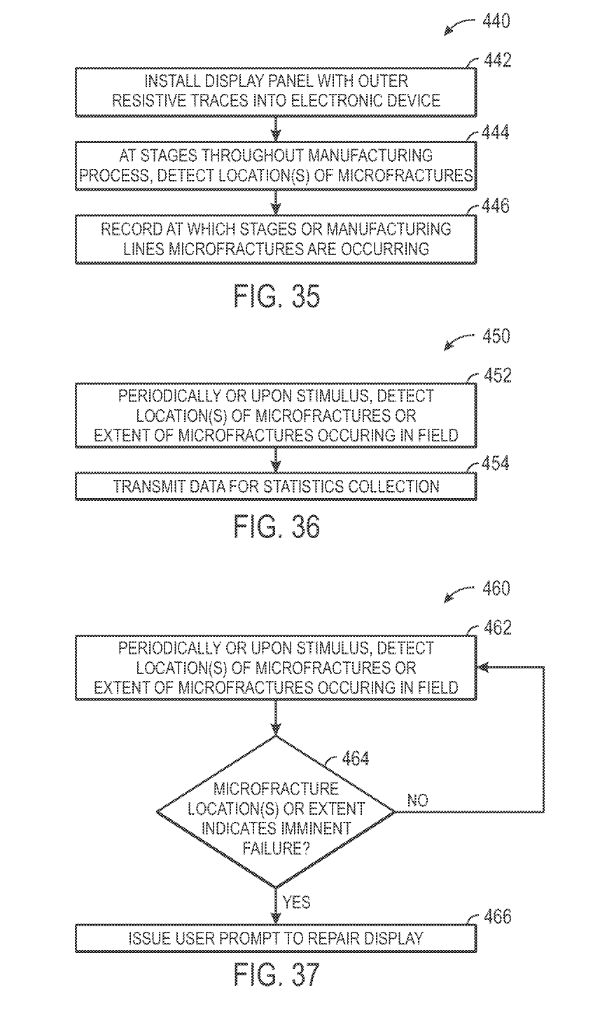

Microfractures that could ultimately result in catastrophic failure are believed to arise in some cases from errors in the manufacturing process of an electronic device 10 that includes a display 18 with a display panel 60. Thus, as illustrated by a flowchart 440 of FIG. 35, the systems 400 and 410, as well as any other suitable systems, such as those described above, may be used to detect when and where microfractures may occur during the manufacturing process of an electronic device 10. A human operator and/or display panel integrity monitoring 402, and/or any other suitable data processing circuitry (e.g., the data processing system 84) may be used in carrying out the flowchart 440 of FIG. 35.

The flowchart 440 may begin when a display panel 60 is used in an electronic display 18 that is installed into an electronic device 10 (block 442). At stages throughout the manufacturing process of the electronic device 10, location(s) of microfractures in the display panel 60 of the display 18 may be tested (block 444). For example, TDR circuitry 392 and/or the TDR test circuitry 412 may use time domain reflectance (TDR) to determine the location(s) and/or extent of microfractures. Additionally or alternatively, the resistance of various segments of the outer resistive trace(s) 20 (R₁, R₂, R₃, and/or R₄) may be monitored and/or the relationship between the resistances of the segments may be monitored for changes. Changes in the resistance of the outer resistive trace(s) 20 occurring during the manufacturing process of an electronic device 10 may indicate that a microfracture has occurred in the display panel 60. That is, the segment of the outer resistive trace(s) 20 that increases at some point in the manufacturing process may be understood to indicate the presence of a new fracture or microfracture in the display panel 60.

Over time, the display panel integrity monitoring 402, the data processing system 84, and/or human operators may record at which stages or at which manufacturing lines (e.g., assembly lines or factories) the microfractures tend to occur in the display panels 60 (block 446). Data relating to the occurrence of microfractures in display panels 60 during the manufacturing process may be used to identify stages and/or manufacturing lines that are particularly problematic to enable an appropriate remedy.

Microfractures may also occur from events happening after an electronic device 10 has been manufactured and sold to a user. Determining how, in the hands of a user, microfractures and/or catastrophic display panel 60 failures occur may be particularly useful for improving the design and/or manufacturing process of the electronic device 10. One manner of gaining such information is shown in a flowchart 450 of FIG. 36. The flowchart 450 may begin when the location(s) of microfractures and/or the extent of microfractures are determined to be occurring in a display panel 60 in the hands of a user (block 452). Specifically, the display panel 60 of the electronic display 18 of the electronic device 10 may include the TDR circuitry 392 and/or the resistance detection circuitry 68 to test the outer resistive trace(s) 20 of the display panel 60. Periodically or upon some stimulus (e.g., rapid changes in motion or orientation detected by the motion-sensing circuitry 28), the actions of block 452 may be taken. The data processing system 84 and/or display panel integrity monitoring 402, which may be components of the processor(s) 12 and/or instructions running on the processor(s) 12, may transmit such data (e.g., via the network interface 26) to a network location associated with the manufacturer of the electronic device 10 (e.g., a web location on the Internet) (block 454).

The same detection of microfractures described above with reference to the flowchart 440 of FIG. 36 may be used to warn a user of imminent failure, if appropriate. For example, as shown by a flowchart 460 of FIG. 37, an electronic device 10 may periodically test the display panel of its electronic display 18 for the location(s) of microfractures and/or the extent of microfractures occurring in the hands of the user (block 462). It should be appreciated that the actions of block 462 may occur periodically or upon some stimulus, such as the detection of rapid motion indicated by the motion-sensing circuitry 29.

The processor(s) 12 of the electronic device 10 may determine whether the location(s) of the microfractures and/or the extent of the microfractures indicate the likely imminent failure of the display panel 60 (decision block 464). For example, the likelihood of imminent catastrophic failure of the display panel 60 given the location(s) and/or extent of microfractures may be correlated to statistical experimental data and/or computer modeling data. In one case, given the location(s) and/or extent of microfractures, the display panel 60 may be unlikely to suffer a catastrophic failure due to these microfractures. If so, the electronic device 10 may continue to occasionally detect the location(s) of microfractures or the extent of such microfractures, as discussed above with reference to block 462. Otherwise, if given the location(s) and/or extent of microfractures, the display panel 60 is likely to suffer a catastrophic failure (decision block 464), the electronic device 10 may issue some form of user prompt indicating imminent failure of the display panel 60 is likely (block 466). For example, a prompt may urge the user to repair the display 18 before the display panel 60 suffers a catastrophic failure.

Technical effects of the present disclosure include, among other things, efficient and/or less labor-intensive display panel size verification. Rather than require manual testing with calipers, a display panel size may be tested by measuring the resistance of outer resistive trace(s) at or near the edges of the display panel. This process may also be manual but more quickly performed, or this process may be automated. The outer resistive trace(s) of a display panel may also be used to more efficiently and/or more precisely grind the display panel to size. Moreover, monitoring the occurrence of discontinuities in the outer resistive trace(s) of a display panel (e.g., via time domain reflectance or changes in resistance) may enable the discovery of fractures or microfractures. The detection of fractures or microfractures in display panels may improve display or device manufacturing processes, as well as enable users to be alerted before a catastrophic display failure occurs.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

1. An electronic device comprising:
a display comprising a display panel, wherein the display panel comprises at least one outer resistive trace disposed near edges of the display panel and discontinuity detection circuitry configured to detect an occurrence of a discontinuity of the at least one outer resistive trace; and
data processing circuitry configured to:
determine whether the display panel of the display is likely to suffer a catastrophic failure based at least in part on the occurrence of the discontinuity; and
cause the display to display a user warning when the display panel is likely to suffer the catastrophic failure.

2. The electronic device of claim 1, wherein the discontinuity detection circuitry comprises circuitry configured to apply a signal to the at least one outer resistive trace and detect the occurrence of the discontinuity using time domain reflectance of the signal.

3. The electronic device of claim 1, wherein the discontinuity detection circuitry of the display panel comprises resistance detection circuitry configured to detect the discontinuity by detecting a change in resistance of a first segment of the at least one outer resistive trace.

4. The electronic device of claim 3, wherein the resistance detection circuitry comprises a wheatstone bridge circuit configured to indicate the resistance of the first segment.

5. The electronic device of claim 3, wherein the resistance detection circuitry comprises a wheatstone bridge circuit configured to indicate a relationship of the resistance of the first segment of the at least one outer resistive trace relative to a resistance of a second segment of the at least one outer resistive trace.

6. The electronic device of claim 1, wherein the discontinuity detection circuitry is configured to detect a location or extent, or both, of the discontinuity, and wherein the data processing circuitry is configured to determine whether the display panel of the display is likely to suffer a catastrophic failure based at least in part on the location or the extent, or both, of the discontinuity.

7. A method of manufacturing an electronic device comprising:
installing a display panel into an electronic device in a stage of manufacturing the electronic device, wherein the display panel comprises at least one outer resistive trace near display panel edges; and
testing the at least one outer resistive trace during another stage of manufacturing the electronic device to determine whether a discontinuity at a location in the at least one outer resistive trace has occurred, wherein the discontinuity indicates a fracture or microfracture, or both, in the display panel at the location.

8. The method of claim 7, wherein testing the at least one outer resistive trace comprises using time domain reflectance to identify whether the discontinuity has occurred.

9. The method of claim 7, wherein testing the at least one outer resistive trace comprises comparing a first resistance of a segment of the at least outer resistive trace obtained at a first time to a to a second resistance of the segment of the at least outer resistive trace obtained at a second time, wherein a change in resistance of the segment indicates that the discontinuity has occurred along the segment, wherein the segment indicates the location of the discontinuity.

10. The method of claim 7, comprising, when testing reveals that the discontinuity has occurred, recording the location of the discontinuity and at which stage of manufacturing the electronic device the discontinuity has occurred.

11. The method of claim 7, comprising, when testing reveals that the discontinuity has occurred, determining whether to pass or reject the electronic device based at least in part on the location of the discontinuity.

12. A display panel comprising:
at least one first outer resistive trace disposed near edges of a first side of the display panel; and
discontinuity detection circuitry configured to detect a discontinuity indicative of a fracture or microfracture, or both, at a location along the at least one first outer resistive trace.

13. The display panel of claim 12, wherein the discontinuity detection circuitry comprises circuitry configured to send a signal through the at least one first outer resistive trace and detect the discontinuity at the location based at least in part on time domain reflectance of the signal.

14. The display panel of claim 12, wherein the discontinuity detection circuitry comprises circuitry configured to detect a change in resistance along a segment of the at least one outer resistive trace, wherein the change in resistance is indicative of the discontinuity at the location along the segment.

15. The display panel of claim 12, comprising at least one second outer resistive trace disposed near edges of a second side of the display panel, wherein the discontinuity detection circuitry is configured to detect a discontinuity indicative of a fracture or microfracture, or both, at a location along the at least one second outer resistive trace.

16. A method comprising:
obtaining a display panel having at least one outer resistive trace disposed near edges of the display panel; and
detecting a location of a fracture or microfracture, or both, occurring in the display panel, by detecting a change in resistance of at least one segment of the at least one outer resistive trace or by detecting a discontinuity of the at least one outer resistive trace using time domain reflectance, or a combination thereof.

17. The method of claim 16, wherein the display panel comprises a first outer resistive trace disposed on an upper side of the display panel and a second outer resistive trace disposed on a lower side of the display panel, and wherein detecting the location of the fracture or microfracture, or both, comprises detecting whether the fracture or microfracture, or both, occur on the upper side of the display panel or the lower side of the display panel.

18. The method of claim 16, wherein detecting the discontinuity using time domain reflectance comprises sending a signal through the at least one outer resistive trace and detecting the location via time domain reflectance of the signal.

19. The method of claim 16, wherein detecting the location of the fracture or microfracture comprises detecting an increase in the resistance of the at least one segment of the at least one outer resistive trace.

20. The method of claim 16, comprising determining an extent of the fracture or microfracture, or both, occurring in the display panel based at least in part on a magnitude of a change in resistance of the at least one segment or a magnitude of a reflected signal, or a combination thereof.

21. The method of claim 20, comprising determining whether to pass or reject the display panel based at least in part on the location or the extent, or both the location and the extent, of the fracture or microfracture, or both.

22. An article of manufacture comprising:
one or more tangible, machine-readable media at least collectively comprising processor-executable instructions comprising:
instructions to cause discontinuity detection circuitry associated with a display panel to detect whether a discontinuity has occurred in at least one outer resistive trace patterned on the display panel;
instructions to receive an indication of whether a discontinuity has been detected by the discontinuity detection circuitry; and
instructions to send a message to an Internet location indicating whether the discontinuity has been detected by the discontinuity detection circuitry.

23. The article of manufacture of claim 22, comprising instructions to carry out the instructions upon receipt of an indication from motion-sensing circuitry of a rapid change in motion.

24. The article of manufacture of claim 22, comprising instructions to carry out the instructions periodically.

25. The article of manufacture of claim 22, comprising instructions to receive, when the discontinuity has been detected, an indication of a location or an extent of the discontinuity and comprising instructions to determine whether the display panel is likely to suffer catastrophic failure based at least in part on the location or the extent of the discontinuity.

26. The article of manufacture of claim 25, comprising instructions to cause, when the display panel is likely to suffer catastrophic failure, the display panel to display a prompt indicating as such.

27. The article of manufacture of claim 25, comprising instructions, when the display panel is likely to suffer catastrophic failure, to send a message to the Internet location indicating as such.

28. A method comprising:
obtaining a patterned device having at least one outer resistive trace disposed near edges of the patterned device; and
detecting a location of a fracture or microfracture, or both, occurring in the patterned device, by detecting a change in resistance of at least one segment of the at least one outer resistive trace or by detecting a discontinuity of the at least one outer resistive trace using time domain reflectance, or a combination thereof.

29. The method of claim 28, wherein the patterned device comprises a display panel, a touch sensor panel, a flexible printed circuit, or a printed circuit board, or a combination thereof.
